(19) United States
(12) Patent Application Publication
(10) Pub. No.: US 2022/0051139 A1
(43) Pub. Date: Feb. 17, 2022

(54) WIRELESS DEVICE, A NETWORK NODE AND METHODS THEREIN FOR TRAINING OF A MACHINE LEARNING MODEL

(71) Applicant: Telefonaktiebolaget LM Ericsson (publ), Stockholm (SE)

(72) Inventors: Hugo TULLBERG, Nyköping (SE); Johan OTTERSTEN, Stockholm (SE)

(21) Appl. No.: 17/416,732

(22) PCT Filed: Dec. 28, 2018
(86) PCT No.: PCT/SE2018/051372

§ 371 Date: Jun. 21, 2021

(51) Int. Cl. G06N 20/00; H04W 28/06

(52) U.S. Cl. CPC G06N 20/00; H04W 28/06

(57) ABSTRACT

A wireless device and a method therein for assisting a network node to perform training of a machine learning model. The wireless device collects a number of successive data samples. Further, the wireless device successively creates compressed data by associating each collected data sample to a cluster. The cluster has a cluster centroid, a cluster counter representative of a number of collected data samples determined to be normal and being associated with the cluster, and a number of outlier collected data samples associated with the cluster. Then, the wireless device updates the cluster centroid to correspond to a mean position of all normal data samples that are associated with the cluster, and increases the cluster counter by one for each normal data sample that is associated with the cluster. The wireless device transmits the compressed data to the network node.

### TECHNICAL FIELD

Embodiments herein relate generally to a wireless device, a network node and to methods therein. In particular, embodiments relate to the training of a machine learning model.

### BACKGROUND

In a typical wireless communication network, communications devices, also known as wireless communication devices, wireless devices, mobile stations, stations (STA) and/or User Equipments (UEs), communicate via a Local Area Network such as a WiFi network or a Radio Access Network (RAN) to one or more Core Networks (CN). The RAN covers a geographical area which is divided into service areas or cell areas, which may also be referred to as a beam or a beam group, with each service area or cell area being served by a Radio Network Node (RNN) such as a radio access node e.g., a Wi-Fi access point or a Radio Base Station (RBS), which in some networks may also be denoted, for example, a NodeB, eNodeB (eNB), or gNB as denoted in 5G. A service area or cell area is an area, e.g. a geographical area, where radio coverage is provided by the radio network node. The radio network node communicates over an air interface operating on radio frequencies with the communications device within range of the radio network node.

Specifications for the Evolved Packet System (EPS), also called a Fourth Generation (4G) network, have been completed within the 3rd Generation Partnership Project (3GPP) and this work continues in the coming 3GPP releases, for example to specify a Fifth Generation (5G) network also referred to as 5G New Radio (NR). The EPS comprises the Evolved Universal Terrestrial Radio Access Network (E-UTRAN), also known as the Long Term Evolution (LTE) radio access network, and the Evolved Packet Core (EPC), also known as System Architecture Evolution (SAE) core network. E-UTRAN/LTE is a variant of a 3GPP radio access network wherein the radio network nodes are directly connected to the EPC core network rather than to RNCs used in 3G networks. In general, in E-UTRAN/LTE the functions of a 3G RNC are distributed between the radio network nodes, e.g. eNodeBs in LTE, and the core network. As such, the RAN of an EPS has an essentially “flat” architecture comprising radio network nodes connected directly to one or more core networks, i.e. they are not connected to RNCs. To compensate for that, the E-UTRAN specification defines a direct interface between the radio network nodes, this interface being denoted the X2 interface.

Multi-antenna techniques used in Advanced Antenna Systems (AAS) can significantly increase the data rates and reliability of a wireless communication system. The performance is in particular improved if both the transmitter and the receiver are equipped with multiple antennas, which results in a Multiple-Input Multiple-Output (MIMO) communication channel. Such systems and/or related techniques are commonly referred to as MIMO systems.

Machine Learning (ML) will become an important part of current and future wireless communications networks and systems. In this disclosure the terms machine learning and ML may be used interchangeably. Recently, machine learning has been used in many different communication applications and shown great potential. As ML becomes increasingly utilized and integrated in the communications system, a structured architecture is needed for communicating ML information between different nodes operating in the communications system. Some examples of such nodes are wireless devices, radio network nodes, core network nodes, computer cloud nodes just to give some examples. Usage of the communications system and the realization of the communications system, including the radio communication interface, the network architecture, interfaces and protocols will change when Machine Intelligence (MI) capabilities are ubiquitously available to all types of nodes in and end-users of a communication system. In this disclosure the terms machine intelligence and MI may be used interchangeably.

In general, the term Artificial Intelligence (AI) comprises reasoning, knowledge representation, planning, learning, natural language processing, perception and the ability to move and manipulate objects. Hence Machine Learning (ML) is sometimes considered as a subfield of AI. In this disclosure, the term Machine Intelligence (MI) is used to comprise both AI and ML. Further, in this disclosure the terms AI, MI and ML may be used interchangeably.

### SUMMARY

As part of developing embodiments herein, some drawbacks with the state of the art communications system will first be identified and discussed.

In some wireless communications system training of a machine learning model may be difficult to accomplish. For example, this may be the case in wireless communications system comprising network nodes that have limited machine learning capabilities and in wireless communications system wherein the training of the machine learning model may be prohibitively complex due to limited computation power and/or limited storage capabilities and/or limited power supply. Sometimes the reason for limiting the computation and storage ability is the power supply, e.g. for battery powered devices.

By the expression “network node with limited machine learning capabilities” when used in this disclosure is meant a network node that is not able to perform training of a machine learning model. This may be due to limited computation power and/or limited storage capabilities and/or limited power supply.

In such wireless communications systems, an alternative is to train the machine learning model elsewhere, i.e. in a network node with more machine learning capabilities, e.g., a base station (BS). However, the network node, e.g. the network node with limited machine learning capabilities, then needs to transmit the training data to a network node capable of machine learning.

However, it is not possible to transmit all training data in its raw form to one or more other network nodes in a Machine Learning Architecture (MLA) since it may take too much communication resources and competes with the user traffic. In case of low-level training data, e.g., Channel State Information (CSI) or Modulation and Coding Subsystem (MCS) indices for the communications link itself, then the amount of data will be huge. The training data thus must be compressed somehow before transmission. Direct averaging per feature may remove structure of the data and is not desirable.

Embodiments disclosed herein describe a method to compress training data in a network node, e.g. a network node with limited ML capabilities, such as a wireless device, while maintaining relevant structure of the data.

Principal Component Analysis (PCA) may reduce the dimensionality of the training set. However, averaging per feature, either direct or after PCA, may remove useful structure in the data.

In order to avoid machine learning communication, e.g. a transmission of training data for remote training, to compete with user communication, the training data may be stored locally until the user communication load diminishes. Then, the training data is sent to a network node, such as an eNB, a cloud node or to any other network node capable of processing the training data. However, such a straightforward implementation will require large storage capability. It will also require transmission of all training data. Thus, such an approach is impractical except for very small sets of training data. Therefore, some embodiments herein provide for storing of training data without the requirement of large memory sizes.

In this disclosure it is described how to use weighted representative examples of the training data, e.g., cluster centroids and cluster counters to keep track of the number of cluster members. Anomaly detection may be used to identify and store individual training examples, so called “outliers”, that are not sufficiently well represented by the cluster centroids, since these examples may be important. The weighted representatives of the training data are sometimes in this disclosure referred to as compress data.

An outlier is an observation point that is distant from other observations. Outliers may occur by chance in any distribution, and indicate either measurement error or that the population has a heavy-tailed distribution. In the former case one may discard them or use statistics that are robust to outliers, while in the latter case they indicate that the distribution has high skewness and that one should be very cautious in using tools or intuitions that assume a normal distribution. In large samples, a small number of outliers is to be expected (and not due to any anomalous condition).

The compressed data, such as the cluster centroids and cluster counters, and individual “outliers”, may be stored locally until the user communication load diminishes to a level where the communication of machine learning data is feasible. When this occurs, the stored compressed data is transmitted to a node capable of machine learning training, a machine learning model is trained base on the transmitted data and possibly the machine learning model is updated.

If one or more covariance matrices and/or principal components for the clusters are determined, the network node performing the training may generate random data according to the distributions, thus avoiding repeated training on identical data. The training points identified by the anomaly detection, e.g. the outliers, are used in their original form.

Some embodiments disclosed herein relates to methods for successive computation of cluster centroids, and of the associated covariances used for PCA and anomaly detection. In some embodiments disclosed herein, no assumptions about the data set in terms of distribution, dimension, order of samples, etc., are made. Thus, some embodiments disclosed herein are applicable to all kinds of distributions. The term distribution refers to the probability distribution, if the points are distributed according to a Gaussian, or any other distribution. The term “dimension” is how many input parameters there are. In the examples given herein two dimensions are shown to be able to draw figures, but in general, the input to a machine learning model may have very many dimensions, i.e. numbers of inputs. The term “dimension” is sometimes in this disclosure referred to as “feature”, and it should be understood that the terms “dimension” and “feature” may be used interchangeably. The expression “order of the samples” is about if points arrives form one cluster at the time. For example, if a user is stationary for a while and then moves, there may be many inputs from a first cluster first, and then as the user moves to another location, from another cluster, and so on. This affects how to merge and split clusters. This may be most relevant for the initialization, when determining the number clusters and where the centroids are located.

According to developments of wireless communications systems an improved usage of resources in the wireless communications system is needed for improving the performance of the wireless communications system.

Therefore, an object of embodiments herein is to overcome the above-mentioned drawbacks among others and to improve the performance in a wireless communications system.

According to an aspect of embodiments herein, the object is achieved by a method performed in a wireless device for assisting a network node to perform training of a machine learning model. The wireless device and the network node operate in a wireless communications system.

The wireless device collects a number of successive data samples for training of the machine learning model comprised in the network node.

The wireless device successively creates compressed data by associating each collected data sample to a cluster. The cluster has a cluster centroid, a cluster counter representative of a number of collected data samples determined to be normal and being associated with the cluster, and a number of outlier collected data samples associated with the cluster. The number of outlier collected data samples is a number of collected data samples determined to be anomalous with respect to the cluster. Further, the wireless device updates the cluster centroid to correspond to a mean position of all normal data samples that are associated with the cluster, and increases the cluster counter by one for each normal data sample that is associated with the cluster.

Further, the wireless device transmits, to the network node, the compressed data comprising the cluster centroid, the cluster counter, and the number of outlier collected data samples, which compressed data is to be used in the training of the machine learning model.

According to another aspect of embodiments herein, the object is achieved by a wireless device for assisting a network node to perform training of a machine learning model. The wireless device and the network node are configured to operate in a wireless communications system.

The wireless device is configured to collect a number of successive data samples for training of the machine learning model comprised in the network node.

The wireless device is configured to successively create compressed data by associating each collected data sample to a cluster. The cluster has a cluster centroid, a cluster counter representative of a number of collected data samples determined to be normal and being associated with the cluster, and a number of outlier collected data samples associated with the cluster. The number of outlier collected data samples is a number of collected data samples determined to be anomalous with respect to the cluster. Further, the wireless device is configured to update the cluster centroid to correspond to a mean position of all normal data samples that are associated with the cluster, and increases the cluster counter by one for each normal data sample that is associated with the cluster.

Further, the wireless device is configured to transmit, to the network node, the compressed data comprising the cluster centroid, the cluster counter, and the number of outlier collected data samples, which compressed data is to be used in the training of the machine learning model.

According to another aspect of embodiments herein, the object is achieved by a method performed in a network node for training of a machine learning model. The network node and a wireless device operate in a wireless communications system.

The network node receives, from the wireless device, compressed data corresponding to a cluster centroid, a cluster counter, and a number of outlier collected data samples associated with a cluster, which compressed data is a compressed representation of data samples collected by the wireless device.

Further, the network node trains the machine learning model using the received compressed data as input to the machine learning model.

According to another aspect of embodiments herein, the object is achieved by a network node for training of a machine learning model. The network node and a wireless device are configured to operate in a wireless communications system.

The network node is configured to receive, from the wireless device, compressed data corresponding to a cluster centroid, a cluster counter, and a number of outlier collected data samples associated with a cluster, which compressed data is a compressed representation of data samples collected by the wireless device.

Further, the network node is configured to train the machine learning model using the received compressed data as input to the machine learning model.

According to another aspect of embodiments herein, the object is achieved by a computer program, comprising instructions which, when executed on at least one processor, causes the at least one processor to carry out the method performed by the wireless device.

According to another aspect of embodiments herein, the object is achieved by a computer program, comprising instructions which, when executed on at least one processor, causes the at least one processor to carry out the method performed by the network node.

According to another aspect of embodiments herein, the object is achieved by a carrier comprising the computer program, wherein the carrier is one of an electronic signal, an optical signal, a radio signal or a computer readable storage medium.

Since the wireless device creates compressed data to be used by the network node when training the machine learning model and transmits the compressed data to the network node, the load on the communication link between the wireless device and the network node will be lesser than when transmitting unprocessed training data at the same time as the compressed data comprises the most relevant information for the training of the machine learning model. Therefore, a more efficient use of the radio spectrum is provided without reducing the quality of the training. This results in an improved performance in the wireless communications system.

An advantage with some embodiments herein is that they provide for reduced communications overhead when transmitting training data due to the transmission of compressed training data. In other words, embodiments disclosed herein provides for a significant reduction in the overhead due to the reduced training data volume transmitted compared to sending all the training samples upwards from the wireless device to the network node.

A further advantage with some embodiments is that they provide for reduced storage requirements when storing machine learning data.

A further advantage with embodiments disclosed herein is that they provide for compression of machine learning training data which significantly reduces the memory requirements while keeping outliers of high importance.

A further advantage with some embodiments herein is that training of the machine learning model is separated from the training data collection. The training may be located at any suitable network location or in a computer cloud. An advantage of centralizing the training to the cloud is that the amount of training data is increased. A more centralized location may also get data from more environment types and create better machine learning models, weights, for the different types of wireless devices.

A further advantage with embodiments herein is that they retain fidelity compared to naïve averaging per feature, since the naïve averaging per feature does not include anomaly detection and thus will miss the outliers. For example, the average of 1, 1, 1, and 5 is 2 which do not capture the distribution. Instead it would be better to say average 1 and an outlier at 5.

### BRIEF DESCRIPTION OF DRAWINGS

Examples of embodiments herein will be described in more detail with reference to attached drawings in which:

FIG. 1 is a schematic block diagram illustrating embodiments of a wireless communications system;

FIG. 2 is a flowchart depicting embodiments of a method performed by a wireless device;

FIG. 3 is a schematic block diagram illustrating embodiments of a wireless device;

FIG. 4 is a flowchart depicting embodiments of a method performed by a network node;

FIG. 5 is a schematic block diagram illustrating embodiments of a network node;

FIG. 6 schematically illustrates an example of clustering and anomaly detection for K=3 clusters;

FIG. 7 schematically illustrates an example of data generated from cluster centroids, variances per cluster and anomalies in FIG. 6;

FIG. 8 schematically illustrates values of Mean Square Error (MSE) as a function of the number of clusters;

FIG. 9 schematically illustrates the MSE resulting from a naïve sample add-cluster merge algorithm;

FIG. 10 schematically illustrates the MSE resulting from a successive clustering algorithm disclosed herein;

FIG. 11 schematically illustrates a result of the successive clustering algorithm disclosed herein being used on the data of FIG. 3 when the data is randomized;

FIG. 12 schematically illustrates a result of the successive clustering algorithm disclosed herein being used on the data of FIG. 3 when the data is sorted;

FIGS. 13A and 13B are flowcharts depicting examples of initialization of the K-means cluster and associated parameters according to some embodiments;

FIG. 14 is a flowchart depicting embodiments of a method performed by a wireless device;

FIG. 15 is a combined flowchart and signalling scheme schematically illustrating embodiments of a method performed in a wireless communications system, and

FIGS. 16 to 21 are flowcharts illustrating methods implemented in a communication system including a host computer, a base station and a user equipment.

### DETAILED DESCRIPTION

The machine intelligence according to embodiments herein, should not be considered as an additional layer on top of the communication system, but rather the opposite—the communication in the communications system takes place to allow distribution of the machine intelligence. The end-user, e.g. a wireless device, interacting with a distributed machine intelligence will achieve whatever it is the wireless device wants to achieve. The wireless device may have access to different ML models for different purposes. For example, one purpose may be to predict relevant information about a communication link to reduce the need for measurements and therefore decreasing complexity and overhead in the communications system comprising the communication link. Distributed storage and compute power is included—ever-present, but not infinite.

Machine learning (ML) will become an important part of current and future system. Recently, it has been used in many different communication applications and shown great potential. Embodiments herein provide a method that makes a wireless communications network capable of handling data-driven solutions. The ML according to embodiments herein may be performed everywhere in the wireless communications system based on data generated everywhere.

Throughout the following description similar reference numerals may be used to denote similar elements, units, modules, circuits, nodes, parts, items or features, when applicable. In the Figures, features that appear only in some embodiments are typically indicated by dashed lines.

In the following, embodiments herein are illustrated by exemplary embodiments. It should be noted that these embodiments are not mutually exclusive. Components from one embodiment may be tacitly assumed to be present in another embodiment and it will be obvious to a person skilled in the art how those components may be used in the other exemplary embodiments.

According to embodiments herein, it is provided a way of improving the performance in the wireless communications system by e.g. improving usage of resources in the wireless communications system. However, even if some embodiments described herein relate to improved resource utilization it should be understood that some embodiments disclosed herein, alternatively or additionally, may provide an improved flexibility and/or an improved adaptability.

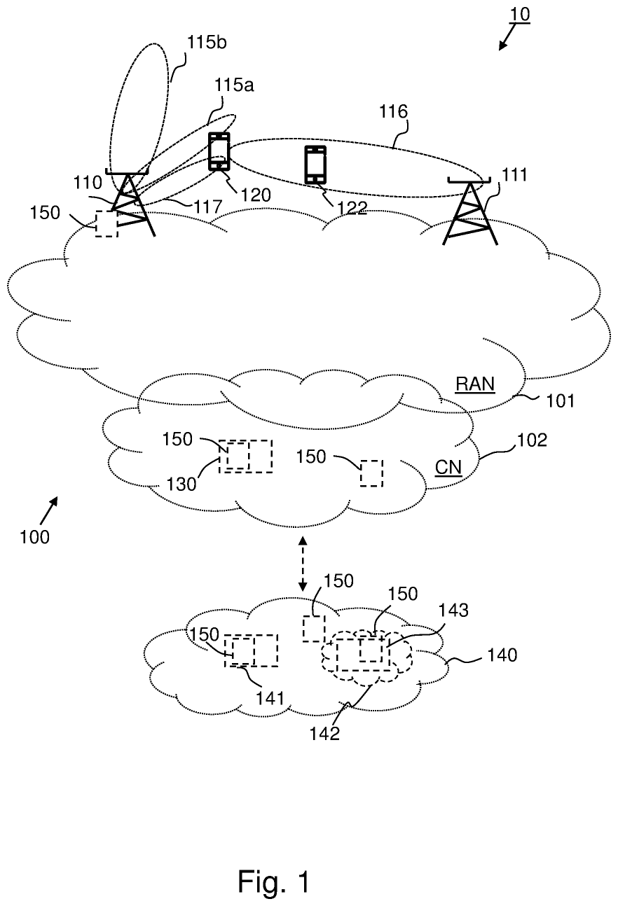

FIG. 1 is a schematic block diagram schematically depicting an example of a wireless communications system 10 that is relevant for embodiments herein and in which embodiments herein may be implemented.

A wireless communications network 100 is comprised in the wireless communications system 10. The wireless communications network 100 may comprise a Radio Access Network (RAN) 101 part and a Core Network (CN) 102 part. The wireless communication network 100 is typically a telecommunication network, such as a cellular communication network that supports at least one Radio Access Technology (RAT), e.g. New Radio (NR) that also may be referred to as 5G. The RAN 101 is sometimes in this disclosure referred to as an intelligent RAN (iRAN). By the expression “intelligent RAN (IRAN)” when used in this disclosure is meant a RAN comprising and/or providing machine intelligence, e.g. by means of a device that perceives its environment and takes actions that maximize its chance of successfully achieving its goals. The machine intelligence may be provided by means of a machine learning unit as will be described below. Thus, the iRAN is a RAN that e.g. has the AI capabilities described in this disclosure.

The wireless communication network 100 comprises network nodes that are communicatively interconnected. The network nodes may be logical and/or physical and are located in one or more physical devices. The wireless communication network 100 comprises one or more network nodes, e.g. a radio network node 110, such as a first radio network node, and a second radio network node 111. A radio network node is a network node typically comprised in a RAN, such as the RAN 101, and/or that is or comprises a radio transmitting network node, such as a base station, and/or that is or comprises a controlling node that controls one or more radio transmitting network nodes.

The wireless communication network 100, or specifically one or more network nodes thereof, e.g. the first radio network node 110 and the second radio network node 111, may be configured to serve and/or control and/or manage and/or communicate with one or more communication devices, such as a wireless device 120, using one or more beams, e.g. a downlink beam 115a and/or a downlink beam 115b and/or a downlink beam 116 provided by the wireless communication network 100, e.g. the first radio network node 110 and/or the second radio network node 111, for communication with said one or more communication devices. Said one or more communication devices may provide uplink beams, respectively, e.g. the wireless device 120 may provide an uplink beam 117 for communication with the wireless communication network 100.

Each beam may be associated with a particular Radio Access Technology (RAT). As should be recognized by the skilled person, a beam is associated with a more dynamic and relatively narrow and directional radio coverage compared to a conventional cell that is typically omnidirectional and/or provides more static radio coverage. A beam is typically formed and/or generated by beamforming and/or is dynamically adapted based on one or more recipients of the beam, such as one of more characteristics of the recipients, e.g. based on which direction a recipient is located. For example, the downlink beam 115a may be provided based on where the wireless device 120 is located and the uplink beam 117 may be provided based on where the first radio network node 110 is located.

The wireless device 120 may be a mobile station, a non-access point (non-AP) STA, a STA, a user equipment and/or a wireless terminals, an Internet of Things (IoT) device, a Narrow band IoT (NB-IoT) device, an eMTC device, a CAT-M device, an MBB device, a WiFi device, an LTE device and an NR device communicate via one or more Access Networks (AN), e.g. RAN, to one or more core networks (CN). It should be understood by the skilled in the art that “wireless device” is a non-limiting term which means any terminal, wireless communication terminal, user equipment, Device to Device (D2D) terminal, or node e.g. smart phone, laptop, mobile phone, sensor, relay, mobile tablets or even a small base station communicating within a cell.

Moreover, the wireless communication network 100 may comprise one or more central nodes, e.g. a central node 130 i.e. one or more network nodes that are common or central and communicatively connected to multiple other nodes, e.g. multiple radio network nodes, and may be configured for managing and/or controlling these nodes. The central nodes may e.g. be core network nodes, i.e. network nodes part of the CN 102.

The wireless communication network, e.g. the CN 102, may further be communicatively connected to, and thereby e.g. provide access for said communication devices, to an external network 140, e.g. the Internet. The wireless device 120 may thus communicate via the wireless communication network 100, with the external network 140, or rather with one or more other devices, e.g. servers and/or other communication devices connected to other wireless communication networks, and that are connected with access to the external network 140.

Moreover, there may be one or more external nodes, e.g. an external node 141, for communication with the wireless communication network 100 and node(s) thereof. The external node 141 may e.g. be an external management node. Such external node may be comprised in the external network 140 or may be separate from this.

Furthermore, the one or more external nodes may correspond to or be comprised in a so called computer, or computing, cloud, that also may be referred to as a cloud system of servers or computers, or simply be named a cloud, such as a computer cloud 142, for providing certain service(s) to outside the cloud via a communication interface. In such embodiments, the external node may be referred to as a cloud node or cloud network node 143. The exact configuration of nodes etc. comprised in the cloud in order to provide said service(s) may not be known outside the cloud. The name “cloud” is often explained as a metaphor relating to that the actual device(s) or network element(s) providing the services are typically invisible for a user of the provided service(s), such as if obscured by a cloud. The computer cloud 142, or typically rather one or more nodes thereof, may be communicatively connected to the wireless communication network 100, or certain nodes thereof, and may be providing one or more services that e.g. may provide, or facilitate, certain functions or functionality of the wireless communication network 100 and may e.g. be involved in performing one or more actions according to embodiments herein. The computer cloud 203 may be comprised in the external network 140 or may be separate from this.

One or more higher layers of the communications network and corresponding protocols are well suited for cloud implementation. By the expression higher layer when used in this disclosure is meant an OSI layer, such as an application layer, a presentation layer or a session layer. The central layers, e.g. the higher levels, of the iRAN architecture are assumed to have wide or global reach and thus expected to be implemented in the cloud.

One advantage of a cloud implementation is that data may be shared between different machine learning models, e.g. between machine learning models for different communications links. This may allow for a faster training mode by establishing a common model based on all available input. During a prediction mode, separate machine learning models may be used for each site or communications link. The machine learning model corresponding to a particular site or communications link may be updated based on data, such as ACK/NACK, from that site. Thereby, machine learning models optimized to the specific characteristic of the site are obtained.

By the term “site” when used in this disclosure is meant a location of a device radio network node, e.g. the first and/or the second radio network node 110,111.

Another advantage with a cloud implementation is that one or more of the machine learning functions described herein to be performed in the network node 110 may be moved to the cloud and to performed by the cloud network node 143.

It should be under stood that functions for user communication, such as payload communication, may not be collocated with functions for ML communication.

One or more machine learning units 150 are comprised in the wireless communications system 10. Thus, it should be understood that the machine learning unit 150 may be comprised in the wireless communications network 100 and/or in the external network 140. For example, the machine learning unit 150 may be a separate unit operating within the wireless communications network 100 and/or the external network 140 and/or it may be comprised in a node operating within the wireless communications network 100 and/or the external network 140. In some embodiments, a machine learning unit 150 is comprised in the radio network node 110. Additionally or alternatively, the machine learning unit 150 may be comprised in the core network 102, such as e.g. in the central node 130, or it may be comprised in the external node 141 or in the computer cloud 142 of the external network 140.

Attention is drawn to that FIG. 1 is only schematic and for exemplifying purpose and that not everything shown in the figure may be required for all embodiments herein, as should be evident to the skilled person. Also, a wireless communication network or networks that in reality correspond(s) to the wireless communication network 100 will typically comprise several further network nodes, such as core network nodes, e.g. base stations, radio network nodes, further beams, and/or cells etc., as realized by the skilled person, but which are not shown herein for the sake of simplifying.

Note that actions described in this disclosure may be taken in any suitable order and/or be carried out fully or partly overlapping in time when this is possible and suitable. Dotted lines attempt to illustrate features that may not be present in all embodiments.

Any of the actions below may when suitable fully or partly involve and/or be initiated and/or be triggered by another, e.g. external, entity or entities, such as device and/or system, than what is indicated below to carry out the actions. Such initiation may e.g. be triggered by said another entity in response to a request from e.g. the device and/or the wireless communication network, and/or in response to some event resulting from program code executing in said another entity or entities. Said another entity or entities may correspond to or be comprised in a so called computer cloud, or simply cloud, and/or communication with said another entity or entities may be accomplished by means of one or more cloud services.

Examples of a method performed by the wireless device 120 for assisting the network node 110 to perform training of a machine learning model will now be described with reference to flowchart depicted in FIG. 2. As previously mentioned, the wireless device 120 and the network node 110 operate in the wireless communications system 10. The machine leaning model may be a representation of one or more wireless devices, e.g. the wireless device 120, 122, and of one or more network nodes, e.g. the network node 110, 111, operating in the wireless communications system 10 and of one or more communications links between the one or more wireless devices and the one or more network nodes. The machine learning model may comprise an input layer, an output layer and one or more hidden layers, wherein each layer comprises one or more artificial neurons linked to one or more other artificial neurons of the same layer or of another layer; wherein each artificial neuron has an activation function, an input weighting coefficient, a bias and an output weighting coefficient, and wherein the weighting coefficients and the bias are changeable during training of the machine learning model.

The method comprises one or more of the following actions. It should be understood that these actions may be taken in any suitable order and that some actions may be combined.

Action 201

The wireless device 120 collects a number of successive data samples for training of the machine learning model comprised in the network node 110. The data samples may for example be sensor readings, such as temperature reading, or communication parameters, such as parameters of a communication link between the wireless device 120 and the network node 110. Some examples of such parameters are load, signal strength, signal quality, just to give some example. It should be understood that embodiments herein are not limited to compressing communication-related data but may be used for any kind of data. Examples of communication data may be beams, modulation and coding schemes, log-likelihood ratios which may computed when knowing the MCS and SNR before doing the channel decoding, and precoder matrix indices, just to mention some examples.

By the term “successive data samples” when used in this disclosure is meant that two or more data samples are obtained one at a time and following each other. The successive data samples may also be referred to as consecutive data samples.

Further, the wireless device 120 may collect the number of successive data samples in several ways. For example, the wireless device 120 may collect the number of successive data samples by performing one or more measurements, by receiving the number of successive data sample from another device, e.g. another wireless device or a network node, e.g. the network node 110, operating in the communications system 100.

Furthermore, the wireless device 120 may be triggered to collect the number of successive data samples by a communications event. For example, the wireless device 120 may be triggered to collect the data samples when a transmission was not transmitted or received as expected.

Sometimes in this disclosure the collected data samples are referred to as training data and it should be understood that the terms may be used interchangeably.

Action 202

The wireless device 120 successively creates compressed data. As will be described in Action 204 below, the wireless device 120 is to transmit the collected data samples to another node, e.g. the network node 110, for centralized training of the machine learning model and in order to reduce the amount of data to be transmitted, the wireless device 120 creates the compressed data. The actions performed by the wireless device 120 to create the compressed data will now be described.

Firstly, the wireless device 120 associates each collected data sample to a cluster. The cluster is a group of one or more collected data samples that are close to each other. The cluster has a cluster centroid, a cluster counter representative of a number of collected data samples determined to be normal and being associated with the cluster, and a number of outlier collected data samples associated with the cluster. The number of outlier collected data samples is a number of collected data samples determined to be anomalous with respect to the cluster. Thus, the normal data samples are normal in the sense that they belong to one of cluster, and then a number, e.g. a small number, of data samples do not, and those anomalies are treated separately as outlier collected data sample in order to capture one or more possible important exceptions.

Secondly, the wireless device 120 updates the cluster centroid to correspond to a mean position of all normal data samples that are associated with the cluster.

Thirdly, the wireless device 120 increases the cluster counter by one for each normal data sample that is associated with the cluster.

In some embodiments, the wireless device 120 successively creates the compressed data by performing the following actions. The wireless device 120 associates only a single normal data sample out of the number of collected data samples to each cluster such that the normal data sample is the cluster centroid, the number of normal data samples associated with the cluster is one, and the number of outlier collected data samples associated with the cluster is zero. Further, when a number of clusters has reached a maximum number, the wireless device 120 merges one or more of the clusters into a merged cluster by updating the cluster centroid to correspond to a mean position of all associated normal data samples of the one or more clusters. Furthermore, the wireless device 120 determines the cluster counter for the merged cluster to be equal to the number of all normal data samples associated with the one or more clusters. Thus, in some embodiments, each new data sample may be considered as a cluster centroid with an initial covariance matrix of zeros until the memory is full. Thereafter, the wireless device 120 may perform cluster merging until further merges would increase a Mean Square Error (MSE) or a similar metric more than an acceptable threshold.

In some embodiments, the wireless device 120 performs the merging of the one or more clusters into the merged cluster by merging the one or more clusters into the merged cluster when a determined variance value of the merged cluster is lower than the respective variance value of the one or more clusters.

In some embodiments, the wireless device 120 may further perform anomaly detection between the collected data sample and the associated cluster to determine whether the collected data sample is an anomalous data sample or a normal data sample.

Some examples of anomaly detection methods are: density-based, subspace- and correlation-based outlier detection, one-class support vector machines, replicator neural networks, Bayesian Networks, and hidden Markov models.

A lightweight version of the correlation-based outlier detection may be used based on a comparison of the distance between the cluster centroid and the point under consideration compared to the standard deviation of the cluster members.

For example, the wireless device 120 may perform the anomaly detection between the collected data sample and the determined associated cluster by performing one or more of the following actions. Firstly, the wireless device 120 may determine a distance between the cluster centroid of the associated cluster and the collected data sample. The term “distance” when used in this disclosure is to be understood in a general sense, not only as a geometrical distance. In the examples given in the figures it is a geometrical distance for visual clarity, but in a real system it may be difference in data rate, difference in speed of the wireless device, or some other more abstract distance. Secondly, the wireless device 120 may determine the collected data sample to be an anomalous data sample when the distance is equal to or above a threshold value. Thirdly, the wireless device 120 may determine the collected data sample to be a normal data sample when the distance is below the threshold value.

The wireless device 120 may determine a maximum number of clusters to be used based on a storage capacity of the memory 307 storing the compressed data. Additionally or alternatively, the wireless device 120 may determine a maximum number of clusters to be used by increasing a number of clusters until a respective variance value of data samples associated with the respective cluster is below a variance threshold value, i.e. below a threshold value for the variance.

In some embodiments, the wireless device 120 determines one or more directions of a multidimensional distribution of the normal data samples associated with the cluster. In order to remove directions of the multidimensional distribution that do not carry a lot of information and to reduce the description of each data samples, the wireless device 120 may optionally disregard one or more directions of the multidimensional distribution along which the normal data samples have a variance value for the one or more directions that is below a variance threshold value. The wireless device 120 may transmit, to the network node 110, the variance value for the one or more directions of the normal data samples having a variance value above the variance threshold value. Thereby, only the directions of the multidimensional distribution of the data samples carrying the most of the information are transmitted to the network node 110.

Action 203

In some embodiments, the wireless device 120 stores, in a memory 307, the cluster centroid, the cluster counter and the number of outlier collected data samples associated with the cluster as the compressed data. An advantage with the storing of the compressed data as compared to storing of the collected data samples is that the storing of the compressed data requires lesser storage capacity than storing of the collected data samples. Another advantage with the storing of the compressed data is that the wireless device 120 is able to store the data until a point in time when it is desirable or advantageous to transmit the compressed data to the network node 110. For example, it may be advantageous to transmit the compressed data when a load in a communication link to the network node 110 is below a threshold or when it is determined that training of the machine learning model is to be performed. Another reason for transmitting the compressed data may be when the storage of the wireless device is full.

Action 204

The wireless device 120 transmits, to the network node 110, the compressed data comprising the cluster centroid, the cluster counter, and the number of outlier collected data samples, which compressed data is to be used in the training of the machine learning model. Thereby, the compressed data is available for the network node 110 as training data for training of the machine learning model.

In some embodiments, the wireless device 120 transmits the compressed data to the network node 110 by transmitting the compressed data to the network node 110 when a load on a communications link between the wireless device 120 and the network node 110 is below a load threshold value. The wireless device 120 may then remove the transmitted compressed data from the memory 307.

The wireless device 120 may receive, from the network node 110, a request for compressed data to be used in the training of the machine learning model. In response to such a request, the wireless device 120 may transmit the compressed data to the network node 110.

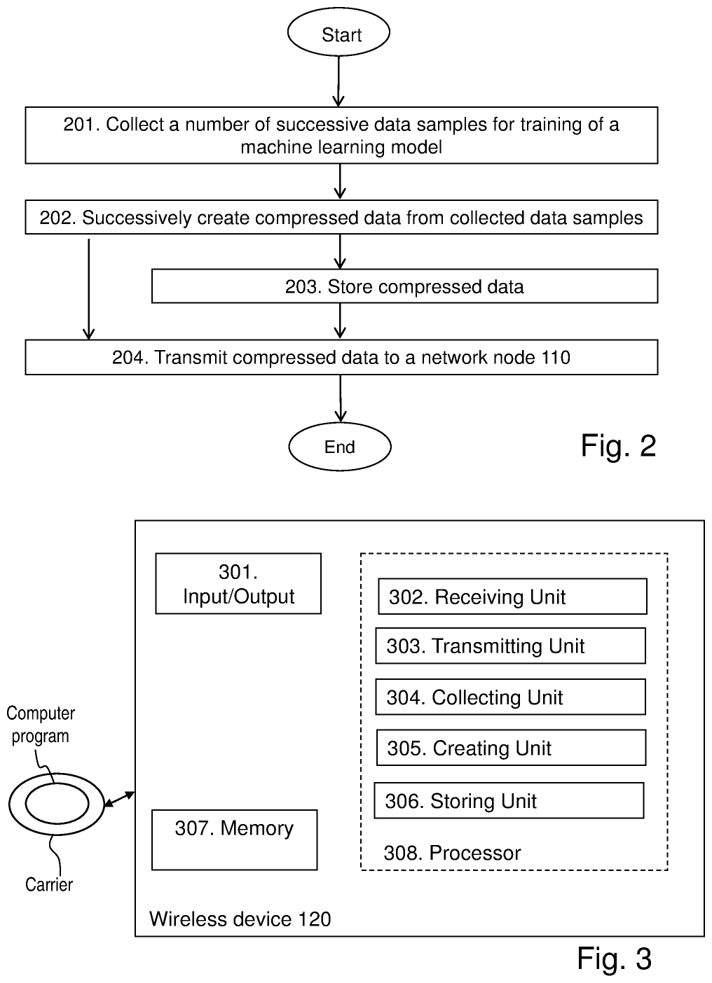

To perform the method for assisting the network node 110 to perform training of a machine learning model, the wireless device 120 may be configured according to an arrangement depicted in FIG. 3. As previously described, the wireless device 120 and the network node 110 are configured to operate in the wireless communications system 10.

In some embodiments, the wireless device 120 comprises an input and/or output interface 301 configured to communicate with one or more other network nodes. The input and/or output interface 301 may comprise a wireless receiver (not shown) and a wireless transmitter (not shown).

The wireless device 120 is configured to receive, by means of a receiving unit 302 configured to receive, a transmission, e.g. a data packet, a signal or information, from another wireless device, e.g. the wireless device 122, from one or more network nodes, e.g. from the network node 110 and/or from one or more external node 141 and/or from one or more cloud node 143. The receiving unit 302 may be implemented by or arranged in communication with a processor 308 of the wireless device 120. The processor 308 will be described in more detail below.

In some embodiments, the wireless device 120 is configured to receive, from the network node 110, a request for compressed data to be used in the training of the machine learning model.

The wireless device 120 is configured to transmit, by means of a transmitting unit 303 configured to transmit, a transmission, e.g. a data packet, a signal or information, to another wireless device, e.g. the wireless device 122, to one or more network nodes, e.g. from the network node 110 and/or to one or more external node 141 and/or to one or more cloud node 143. The transmitting unit 303 may be implemented by or arranged in communication with the processor 308 of the wireless device 120.

The wireless device 120 is configured to transmit, to the network node 110, compressed data comprising a cluster centroid, a cluster counter and a number of outlier collected data samples, which compressed data is to be used in the training of the machine learning model.

In some embodiments, wherein the wireless device 120 is configured to receive, from the network node 110, a request for compressed data to be used in the training of the machine learning model, the wireless device 120 may be configured to transmit the compressed data to the network node 110 in response to the received request.

In some embodiments, the wireless device 120 is configured to determine one or more directions of a multidimensional distribution of the normal data samples associated with the cluster. As previously mentioned and in order to remove directions of the multidimensional distribution that do not carry a lot of information and to reduce the description of each data samples, the wireless device 120 may be configured to optionally disregard one or more directions of the multidimensional distribution along which the normal data samples have a variance value for the one or more directions that is below a variance threshold value. The wireless device 120 may be configured to transmit, to the network node 110, the variance value for the one or more directions of the normal data samples having a variance value above the variance threshold value. Thereby, only the directions of the multidimensional distribution of the data samples carrying the most of the information are transmitted to the network node 110.

In some embodiments, the wireless device 120 is configured to transmit the compressed data to the network node 110 when a load on a communications link between the wireless device 120 and the network node 110 is below a load threshold value. In such embodiments, the wireless device 120 may be configured to remove the transmitted compressed data from the memory 307.

The wireless device 120 may be configured to collect, by means of a collecting unit 304 configured to collect, a data sample. The collecting unit 304 may be implemented by or arranged in communication with the processor 308 of the wireless device 120.

The wireless device 120 is configured to collect a number of successive data samples for training of the machine learning model comprised in the network node 110.

As previously mentioned, the data samples may relate to sensor readings, such as temperature sensor readings or to communications parameters such as signal strength, load, signal quality, etc.

The wireless device 120 is configured to create, by means of a creating unit 305 configured to create, compressed data. The creating module 305 may be implemented by or arranged in communication with the processor 308 of the wireless device 120.

The wireless device 120 is configured to successively create compressed data by being configured to perform one or more of the following actions. The wireless device 120 is configured to associate each collected data sample to a cluster. The cluster has a cluster centroid, a cluster counter representative of a number of collected data samples determined to be normal and being associated with the cluster, and a number of outlier collected data samples associated with the cluster. Further, the number of outlier collected data samples is a number of collected data samples determined to be anomalous with respect to the cluster. Further, the wireless device 120 is configured to update the cluster centroid to correspond to a mean position of all normal data samples that are associated with the cluster, and to increase the cluster counter by one for each normal data sample that is associated with the cluster.

In some embodiments, the wireless device 120 is configured to successively create the compressed data by further being configured to associate only a single normal data sample out of the number of collected data samples to each cluster such that the normal data sample is the cluster centroid, the number of normal data samples associated with the cluster is one, and the number of outlier collected data samples associated with the cluster is zero. In such embodiments and when a number of clusters has reached a maximum number, the wireless device is configured to merge one or more of the clusters into a merged cluster by being configured to update the cluster centroid to correspond to a mean position of all associated normal data samples of the one or more clusters, and by being configured to determine the cluster counter for the merged cluster to be equal to the number of all normal data samples associated with the one or more clusters.

In some embodiments, the wireless device 120 is configured to merge the one or more clusters into the merged cluster by further being configured to merge the one or more clusters into the merged cluster when a determined variance value of the merged cluster is lower than the respective variance value of the one or more clusters.

The wireless device 120 may be configured to successively create the compressed data by further being configured to perform anomaly detection between the collected data sample and the associated cluster to determine whether the collected data sample is an anomalous data sample or a normal data sample.

In some embodiments, the wireless device 120 is configured to perform the anomaly detection between the collected data sample and the determined associated cluster by further being configured to determine a distance between the cluster centroid of the associated cluster and the collected data sample; to determine the collected data sample to be an anomalous data sample when the distance is equal to or above a threshold value; and to determine the collected data sample to be a normal data sample when the distance is below the threshold value.

In some embodiments, the wireless device 120 is configured to determine a maximum number of clusters to be used based on a storage capacity of the memory 307 storing the compressed data.

Alternatively or additionally, the wireless device 120 may be configured to determine a maximum number of clusters to be used by increasing a number of clusters until a respective variance value of data samples associated with the respective cluster is below a variance threshold value.

The wireless device 120 may be configured to store, by means of a storing unit 306, configured to store, compressed data. The storing unit 306 may be implemented by or arranged in communication with the processor 308 of the wireless device 120.

The wireless device 120 may be configured to store, in a memory 307, the cluster centroid, the cluster counter and the number of outlier collected data samples associated with the cluster as the compressed data.

The wireless device 120 may also comprise means for storing data. In some embodiments, the wireless device 120 comprises a memory 307 configured to store the data. The data may be processed or non-processed data and/or information relating thereto. As mentioned above, the compressed data may be stored in the memory 307. The memory 307 may comprise one or more memory units. Further, the memory 307 may be a computer data storage or a semiconductor memory such as a computer memory, a read-only memory, a volatile memory or a non-volatile memory. The memory is arranged to be used to store obtained information, data, configurations, and applications etc. to perform the methods herein when being executed in the wireless device 120.

Embodiments herein for assisting the network node 110 to perform training of the machine learning model may be implemented through one or more processors, such as the processor 308 in the arrangement depicted in FIG. 3, together with computer program code for performing the functions and/or method actions of embodiments herein. The program code mentioned above may also be provided as a computer program product, for instance in the form of a data carrier carrying computer program code for performing the embodiments herein when being loaded into the wireless device 120. One such carrier may be in the form of an electronic signal, an optical signal, a radio signal or a computer readable storage medium. The computer readable storage medium may be a CD ROM disc or a memory stick.

The computer program code may furthermore be provided as program code stored on a server and downloaded to the wireless device 120.

Those skilled in the art will also appreciate that the input/output interface 301, the receiving unit 302, the transmitting unit 303, the collecting unit 304, the creating unit 305, the storing unit 306, or one or more possible other units above may refer to a combination of analogue and digital circuits, and/or one or more processors configured with software and/or firmware, e.g. stored in the memory 307, that when executed by the one or more processors such as the processors in the wireless device 120 perform as described above. One or more of these processors, as well as the other digital hardware, may be included in a single Application-Specific Integrated Circuitry (ASIC), or several processors and various digital hardware may be distributed among several separate components, whether individually packaged or assembled into a System-on-a-Chip (SoC).

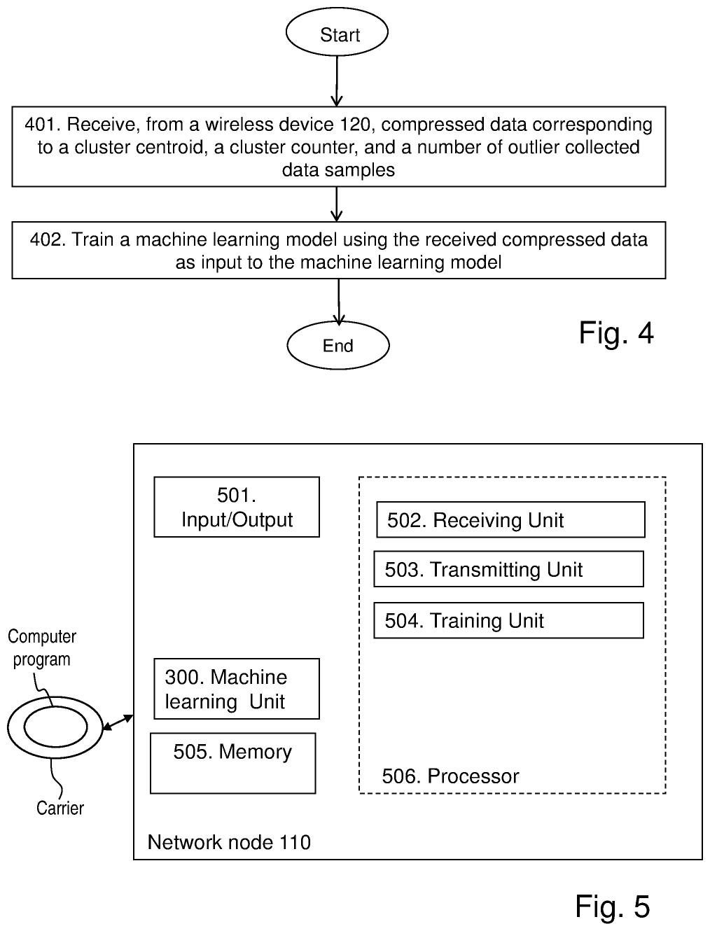

Examples of a method performed by the network node 110 for training of a machine learning model will now be described with reference to flowchart depicted in FIG. 4. As mentioned above, the network node 110 and the wireless device 120 operate in the wireless communications system 10. Further, and as also previously mentioned, the machine leaning model may be a representation of one or more wireless devices, e.g. the wireless device 120, 122, and of one or more network nodes, e.g. the network node 110, 111, operating in the wireless communications system 10 and of one or more communications links between the one or more wireless devices and the one or more network nodes. The machine learning model may comprise an input layer, an output layer and one or more hidden layers, wherein each layer comprises one or more artificial neurons linked to one or more other artificial neurons of the same layer or of another layer; wherein each artificial neuron has an activation function, an input weighting coefficient, a bias and an output weighting coefficient, and wherein the weighting coefficients and the bias are changeable during training of the machine learning model.

The method comprises one or more of the following actions. It should be understood that these actions may be taken in any suitable order and that some actions may be combined.

Action 401

The network node 110 receives compressed data from the wireless device 120, which compressed data is a compressed representation of data samples collected by the wireless device 120. The compressed data corresponds to or comprises a cluster centroid, a cluster counter, and a number of outlier collected data samples associated with a cluster.

Action 402

The network node 110 trains the machine learning model using the received compressed data as input to the machine learning model.

In some embodiments, the network node 110 receives, from the wireless device 120, a variance value per direction of a multidimensional distribution of the collected data samples associated with the cluster. In such embodiments, the network node 110 generates a number of random data samples based on the received cluster centroid and the received variance values, wherein the number of random data samples is proportional to the cluster counter. Further, in such embodiments, the network node 110 may train the machine learning model using the one or more generated random data samples as input to the machine learning model.

For example, the network node 110 may use a random number generator (not shown) with the received cluster centroid as a mean input and the received variance as a variance input to generate the random data samples. The number of generated data samples should be proportional to the cluster counter to get a correct weighting between the clusters.

The network node 110 may, e.g. by means of the machine learning unit 150, train the machine learning model based on received compressed data or based on the one or more generated random data samples.

In some embodiments, the network node 110, e.g. by means of the machine learning unit 150, trains the machine learning model by adjusting weighting coefficients and biases for one or more of the artificial neurons until a known output data is given as an output from the machine learning model when the corresponding known input data is given as an input to the machine learning model. The know output data may be received from the wireless device 120 or it may be stored in the network node 110.

The network node 110 may update the machine learning model based on a result of the training.

To perform the method for training of a machine learning model, the network node 110 may be configured according to an arrangement depicted in FIG. 5. As previously described, the network node 110 and the wireless device 120 are configured to operate in the wireless communications system 10. Further, the network node 110 may be configured to comprise the machine learning unit 150.

In some embodiments, the network node 110 comprises an input and/or output interface 501 configured to communicate with one or more other network nodes. The input and/or output interface 501 may comprise a wireless receiver (not shown) and a wireless transmitter (not shown).

The network node 110 is configured to receive, by means of a receiving unit 502 configured to receive, a transmission, e.g. a data packet, a signal or information, from a wireless device, e.g. the wireless device 120, one or more other network node 111, 130 and/or from one or more external node 201 and/or from one or more cloud node 202. The receiving unit 502 may be implemented by or arranged in communication with a processor 506 of the network node 110. The processor 506 will be described in more detail below.

The network node 110 is configured to receive compressed data from the wireless device 120, which compressed data is a compressed representation of data samples collected by the wireless device 120. The compressed data corresponds to or comprises a cluster centroid, a cluster counter, and a number of outlier collected data samples associated with a cluster.

In some embodiment, the network node 110 is configured to receive, from the wireless device 120, a variance value per direction of a multidimensional distribution of the collected data samples associated with the cluster.

The network node 110 is configured to transmit, by means of a transmitting unit 503 configured to transmit, a transmission, e.g. a data packet, a signal or information, to a wireless device, e.g. the wireless device 120, one or more other network node 111, 130 and/or to one or more external node 201 and/or to one or more cloud node 202. The transmitting unit 503 may be implemented by or arranged in communication with the processor 506 of the network node 110.

The network node 110 is configured to train, by means of a training unit 504 configured to train, a machine learning model. The training unit 504 may be implemented by or arranged in communication with the processor 506 of the network node 110.

The network node 110 is configured to train the machine learning model using the received compressed data as input to the machine learning model.

As mentioned above, in some embodiments, the network node 110 is configured to receive, from the wireless device 120, the variance value per direction of a multidimensional distribution of the collected data samples associated with the cluster. In such embodiments, the network node 110 is configured to generate a number of random data samples based on the received cluster centroid and the received variance values, wherein the number of random data samples is proportional to the cluster counter. Further, in such embodiments, the network node 110 may be configured to train the machine learning model using the one or more generated random data samples as input to the machine learning model.

For example, the network node 110 may be configured to use a random number generator (not shown) with the received cluster centroid as a mean input and the received variance as a variance input to generate the random data samples. The number of generated data samples should be proportional to the cluster counter to get a correct weighting between the clusters.

The network node 110 may, e.g. by means of the machine learning unit 150, be configured to train the machine learning model based on received compressed data or based on the one or more generated random data samples.

In some embodiments, the network node 110, e.g. by means of the machine learning unit 150, is configured to train the machine learning model by adjusting weighting coefficients and biases for one or more of the artificial neurons until a known output data is given as an output from the machine learning model when the corresponding known input data is given as an input to the machine learning model. The know output data may be received from the wireless device 120, e.g. in the transmitted compressed data, or it may be stored in the network node 110.

The network node 110 may be configured to update, by means of an updating unit 417 configured to update, a machine learning model. The updating unit 417 may be implemented by or arranged in communication with the processor 419 of the network node 110, 111, 120, 122, 130.

The network node 110 may be configured to update the machine learning model based on a result of the training.

The network node 110 may also comprise means for storing data. In some embodiments, the network node 110 comprises a memory 505 configured to store the data. The data may be processed or non-processed data and/or information relating thereto. The memory 505 may comprise one or more memory units. Further, the memory 505 may be a computer data storage or a semiconductor memory such as a computer memory, a read-only memory, a volatile memory or a non-volatile memory. The memory is arranged to be used to store obtained information, data, configurations, and applications etc. to perform the methods herein when being executed in the network node 110.

Embodiments herein for training of a machine learning model may be implemented through one or more processors, such as the processor 506 in the arrangement depicted in FIG. 5, together with computer program code for performing the functions and/or method actions of embodiments herein. The program code mentioned above may also be provided as a computer program product, for instance in the form of a data carrier carrying computer program code for performing the embodiments herein when being loaded into the network node 110. One such carrier may be in the form of an electronic signal, an optical signal, a radio signal or a computer readable storage medium. The computer readable storage medium may be a CD ROM disc or a memory stick.

The computer program code may furthermore be provided as program code stored on a server and downloaded to the network node 110.

Those skilled in the art will also appreciate that the input/output interface 501, the receiving unit 502, the transmitting unit 503, the training unit 504, or one or more possible other units above may refer to a combination of analogue and digital circuits, and/or one or more processors configured with software and/or firmware, e.g. stored in the memory 505, that when executed by the one or more processors such as the processors in the network node 110 perform as described above. One or more of these processors, as well as the other digital hardware, may be included in a single Application-Specific Integrated Circuitry (ASIC), or several processors and various digital hardware may be distributed among several separate components, whether individually packaged or assembled into a System-on-a-Chip (SoC).

### Some Exemplifying Embodiments

Some exemplifying embodiments relating to actions and features described above will now be described in more detail.

In some exemplifying embodiments, the communications system 10 comprises a network node 110, e.g. an Access Point (AP) such as an eNB, and two wireless devices 120, 122 of different machine learning capabilities. The eNB is connected to a core network, e.g. the core network 102, and possibly a cloud infrastructure, such as a computer cloud 140. The wireless devices attached to the eNB may be of different machine learning capabilities, such as a first wireless device with capability for ML training, and a second wireless device with limited capability for ML training. A first wireless device, e.g. the wireless device 120, may be a smart phone with capability of ML training and a second wireless device, e.g. the wireless device 122, may be a connected temperature sensor with limited capabilities for ML training.

Perform K-Means Clustering and Anomaly Detection

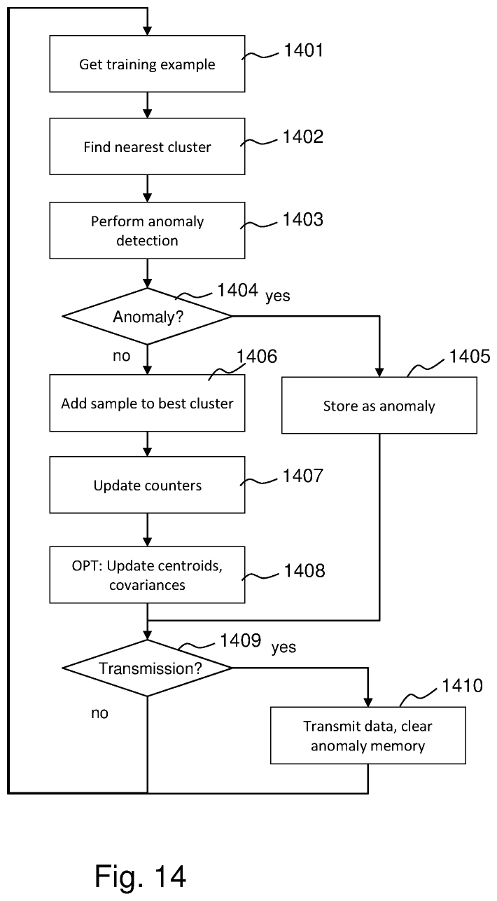

Some embodiments disclosed herein reduce the storage requirement by performing K-means clustering and anomaly detection. For example, this relates to Actions 201-203 described above. Other clustering techniques may be used as well, for example, the Expectation Maximization (EM) algorithm. For each new data sample, the closest cluster centroid is determined. Then the distance to the cluster centroid is determined and compared to a threshold, e.g. a threshold value. If the distance is below the threshold, the data sample is considered as belonging to the cluster and the corresponding cluster counter is incremented by one. If the distance between the new data sample and the cluster centroid is above the threshold, the data sample is considered an outlier, i.e. as an anomaly. In this case the sample is stored as it is, i.e. the full input feature vector is stored. See also the flowchart in FIG. 14.

In some embodiments, a Principal Component Analysis (PCA) or similar analysis per cluster is performed in order to reduce the dimensionality of a ML problem by determining the most important components and/or axes and/or directions of a multidimensional distribution. If the PCA is used for dimensionality reduction, only the most significant directions are retained, and the least significant directions are ignored. The variance along the different directions is used to set a threshold for which directions to keep and ignore. It is also possible to use a Gaussian Mixture Model (GMM) to represent the high-dimensional data. Techniques such as GMM reduction may be used to reduce the dimensionality of the ML problem, and this technique may represent the data quite well.

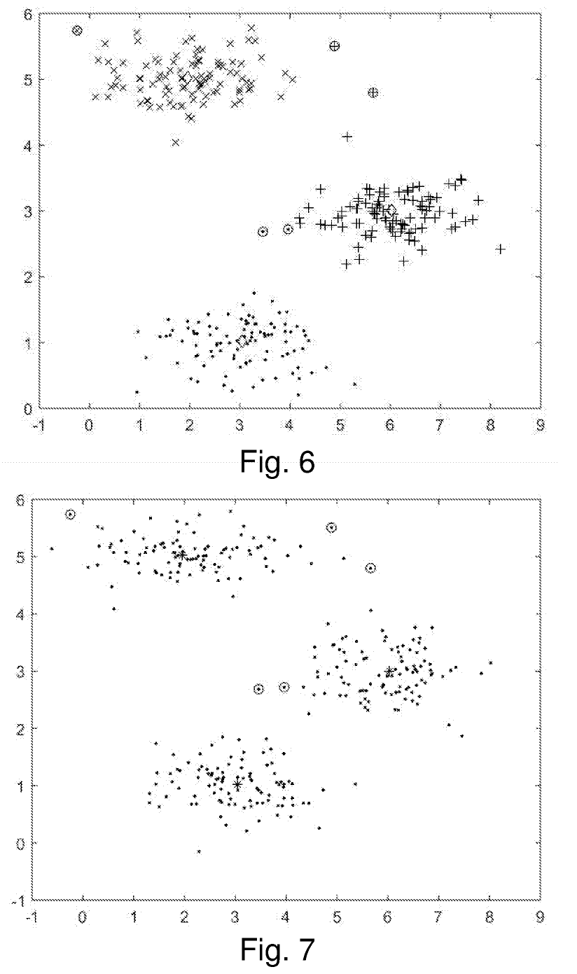

FIG. 6 schematically shows an example of the clustering and anomaly detection for K=3 clusters. In FIG. 6, the outliers are associated with the closest cluster and also identified as outliers, shown with a ring.

Data Transmission from the Wireless Device 120 to a Network Node, e.g. the Network Node 110, Such as the eNB

When a sufficient amount of training data has been collected in the wireless device 120, compressed data is transmitted to the eNB or another central node, such as the core network node 130 or the cloud network node 143. For example, this relates to Action 204 described above. The transmission may be triggered by the wireless device's 120 storage being full, by a predetermined number of data samples have been collected, by a predetermined number of outliers being identified, by a time having expired, by a request from the eNB/central node, or by another relevant mechanism.

The transmitted compressed data comprises the cluster centroids and the number of members in each cluster, and a list of outliers/anomalies. In some embodiments, information regarding the multidimensional distribution for each cluster is also transmitted to the node performing the training. Some examples of such information are the determined axes and variances, or covariance matrix. The training node, e.g. the network node 110, may then use this information to generate random samples according to the distribution and use these for training the ML model, instead of repeated training using the cluster centroids. For example, this relates to Actions 401-402 described above.

The target values are assumed to be known during the training. The target values are provided from outside as a known and/or desirable output. The output from the ML model should be the same as the target or as close to as possible and the training is concerned about making this happen. For classification, the clusters may be divided based on the output data, representative inputs for each class may be stored and anomaly detection as described below may be performed. For regression, the output may be treated as any continuous input feature and used in the clustering and/or anomaly detection.

In some embodiments, the cluster index and the training target, i.e. the target value, are stored for each training example. For anomalous data, the full input feature vector and training target are stored. Alternatively or additionally, the training target may be treated as one or more dimension(s) in the clustering. This representation only requires storing a cluster occurrence counter. In some embodiments disclosed herein the target value is treated as an additional dimension or as more dimensions if the target has more value, or stored separately (additional storage cost, but significantly smaller than the input).

Training in the Network Node, e.g. the Network Node 110 Such as the eNB

For example, this relates to Action 402. At the network node 110 or another other node where training takes place, the ML model is updated based on the received compressed training data. If covariance matrices or other measure of spread in the clusters are not transmitted to the network node 110, the ML model is trained on cluster centroids, either repeated the number of times of members in each cluster, or otherwise weighted. The outliers are used for training as is, since each outlier contains the full feature vector.

If covariance matrices for the clusters are transmitted, the network node 110 may generate random data according to the covariance matrix for each cluster. The outliers are used as is also in this case. FIG. 7 schematically shows an example of generated data. The cluster centroids and outlier are the same as in FIG. 6, but the data points in each cluster are generated in the network node 110 according to the covariance matrices. By generating the ML model training data, instead of using repeated centroids, overfitting is reduced, and a better generalization performance is achieved.

Finding Parameters

For example, this relates to Actions 201-203 described above. Some embodiments disclosed herein, uses a number of parameters for clustering and anomaly detection, e.g., the number of clusters K, the cluster centroids, spreading measures, e.g. the covariance matrices, and anomaly thresholds. If the environment in which the wireless device 120 will be deployed is stable and known, data samples may be collected in advance and the parameters may be computed beforehand and included in the wireless device 120 at manufacturing (possibly updatable during the devices' lifetime). If not, the appropriate parameters need to be found after deployment. Below some methods for this will be described. However, it should be understood that the list is not exhaustive.

Since the wireless device 120 will have to store the cluster centroids, the number of samples per cluster, a number of outliers, and optionally covariance matrices, some memory will be available in the wireless device 120. This memory may be used to make initial calculations of the parameters and then cleared, e.g. emptied, to store the outliers.

Find Optimum Number of Clusters K*

For example, this relates to Actions 201-203 described above. The optimum number of clusters K* may be found using e.g., the one or more out of several methods. One example of such methods is the so called “elbow” method, wherein the number of clusters is increased incrementally until a decrease in “explained variance” falls below some threshold. Another example is to use some information criterion, such as an Akaike Information Criterion (AIC), a Bayesian Information Criterion (BIC), a Deviance Information Criterion (DIC)), or a rate-distortion theory criterion.

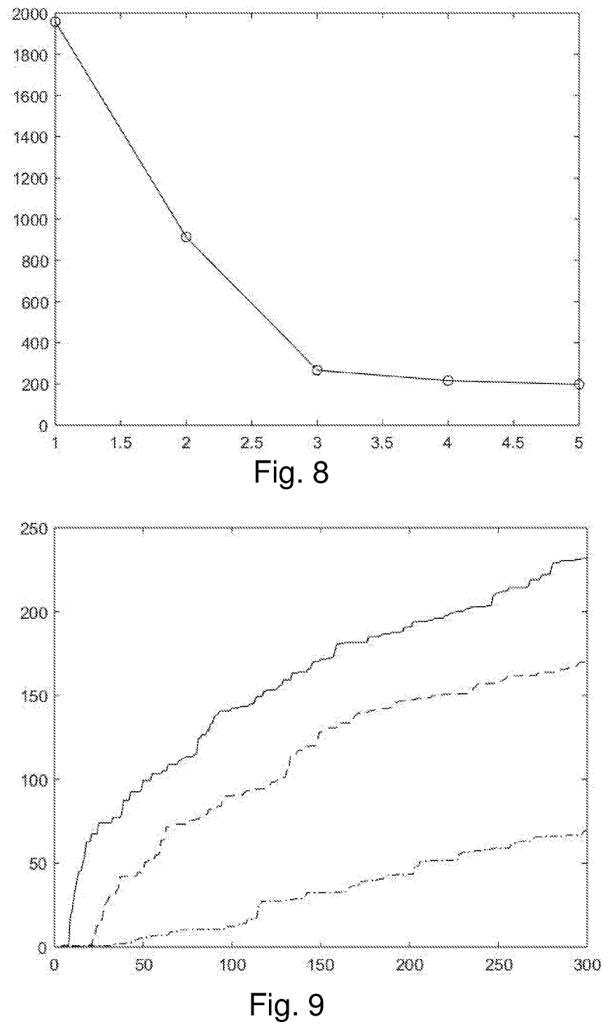

FIG. 8 schematically shows how the Mean Squared Error (MSE) decreases as the number of clusters K increases. In the figure, an “elbow” is visible at K=3, and for K>3, the decrease in MSE reduces. Hence K*=3 for this data set. The reduced MSE decrease is detectable by computations and this method is not limited to visual inspection.

In some embodiments, the number of clusters may depend on the device capabilities. For example, this may be the case when the storage capabilities are limited.

In some embodiment, the number of clusters is adaptive. For example, this may be the case when the devices are mobile, e.g. moving, and the number of cluster changes with the environment in which the device is located.

Determining an Anomaly Threshold

For example, this relates to Actions 201-203 described above. For each cluster, an appropriate probability threshold for anomaly detection may be determined. For a given data set with identifiers identified, one way to do this is to find the probability threshold that maximizes the F1 score:

“precision”=TP/(TP+FP)

recall=TP/(TP+FN)

F_1=2(precision·recall)/(precision+recall)

where TP=True Positives, FP=False Positives, and FN=False Negatives in the classification of anomalies.

The thresholds for the anomaly detection may also be determined based on the covariance matrix for each cluster. The thresholds may be determined either from the original clusters with possible correlations between axes or the orthogonalized axes from the PCA without correlations. If for example GMMs are used to represent the training data, distance/similarity measures between distributions such as the Kullback-Leibler (KL) divergence may be useful for anomaly detection.

Successive Clustering

For example, this relates to Actions 201-203 described above.

In some embodiments, a device memory, e.g. the memory 307, is used to store the first samples and then determine the cluster centroids. Optionally, the number of clusters is determined. When the cluster centroids have been determined, the data samples are associated with the clusters and the cluster-wise PCA and/or covariances for anomaly detection are determined.

In some embodiments, each new data sample is considered as a cluster centroid, with an initial covariance matrix of zeros until the memory is full. Then, cluster merging is performed until further merges would increase the MSE or similar metric more than an acceptable threshold. In FIG. 8 this amounts to starting at large K values and moving to the left until any further decrease would go past the “elbow”. Splitting clusters is less straightforward than merging clusters. Hence, it may be advantageous to be generous with clusters since merging is easier than splitting.

For example, if the optimum number of clusters is K*, the K* first data samples will each be associated with one of the K* clusters. Then each new data samples will be added to add one of the previous K* clusters. Alternatively or additionally, two clusters may be merged and a new cluster is created for the new data sample. FIG. 9 shows the MSE resulting from such a sample add-cluster merge algorithm. The x-axis is the number of samples and the y-axis is the accumulated MSE per cluster.

If for each new data sample the MSE that would result from adding the new data sample to one of the clusters or from merging clusters is calculated, an algorithm that is more complex but results in lower MSE would be obtained. Such an algorithm may for example comprise one or more of the actions below.
Receive a data sample
Compute the MSE that would result from adding the new data sample to one of the K existing clusters.
Compute the MSE that would result from merging all possible pairs of clusters and creating a new cluster consisting only of the new data sample.
From the MSE metrics computed above, select the alternative that results in the lowest MSE.
Add the sample or merge the clusters according to the best alternative, and update cluster centroids, cluster counters and covariance matrices.

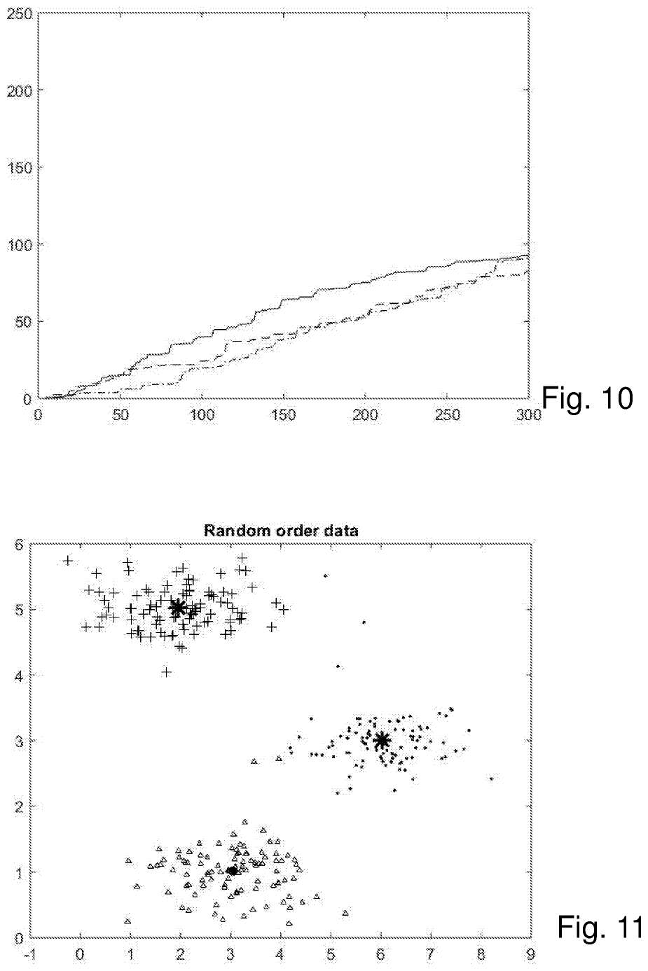

FIG. 10 shows the MSE resulting from such an algorithm. The figure illustrates that the MSE gets lower but there are parameters that may be further optimized. The x-axis is the number of samples compressed/received and the y-axis is the accumulated MSE per cluster. The accumulated MSE increases as a new data point is added to a cluster, or stays the same if the data point is considered as an anomaly.

A stable one-pass algorithm exists, similar to the online algorithm for computing the variance, that computes co-moment:

$${C}_{n} = {\sum }_{i = 1}^{n} ( {x}_{i} - {\overline{x}}_{n} ) ( {y}_{i} - {\overline{y}}_{n} ) : \\ {\overline{x}}_{n} = {\overline{x}}_{n - 1} + \frac{{x}_{n} - {\overline{x}}_{n - 1}}{n}$$

$${\overline{y}}_{n} = {\overline{y}}_{n - 1} + \frac{{y}_{n} - {\overline{y}}_{n - 1}}{n}$$

$${C}_{n} = {C}_{n - 1} + ( {x}_{n} - {\overline{x}}_{n} ) ( {y}_{n} - {\overline{y}}_{n - 1} ) = {C}_{n - 1} + ( {x}_{n} - {\overline{x}}_{n - 1} ) ( {y}_{n} - {\overline{y}}_{n} )$$

The first equation shows how to compute the co-moment when all n samples are available. Since the idea of embodiments described herein is to compress data by adding them to clusters, or treat them as anomalies, as they are encountered, we want to compute the co-moment for the n first received data samples in a recursive manner. That is shown in the lower part.

In the top equation, the means, x\hat{ }bar and y\hat{ }bar, are computed first and then the co-moment. xᵢ is the i-th sample of the n in total.

Further, Cₙ is the co-moment for the n first samples, n is the number of samples, x\hat{ }bar n is the mean of the n first samples, x\hat{ }bar n−1 is the mean of the n−1 first samples, and similarly for y\hat{ }bar n and y\hat{ }bar n−1.

The covariance is then computed as Cₙ/n or Cₙ/(n−1) for the population covariance and sample covariance, resp.

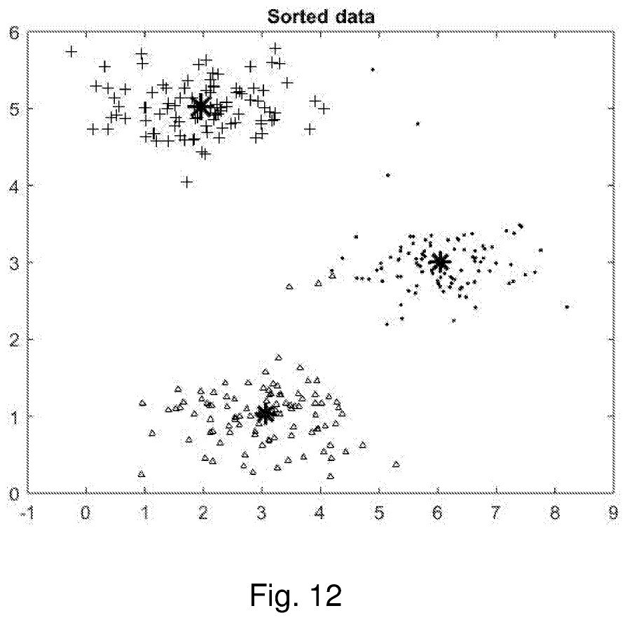

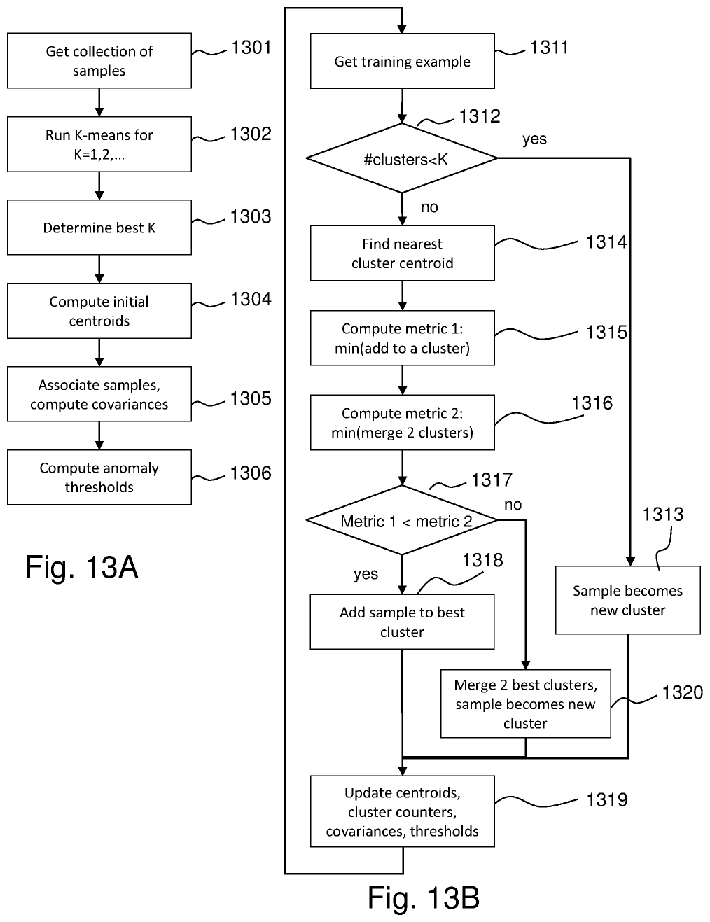

The same data set as used in FIG. 6 has been used to test the successive clustering algorithm. Two experiments have been performed, one experiment wherein the data points are sorted, e.g. all points associated with one cluster first, then all associated with the second, and so on, and one experiment wherein the points are randomized. The proposed algorithm performs well on both sets of data points, see FIGS. 11 and 12.

FIGS. 13A and 13B schematically shows two examples of how to determine the clustering parameters as described earlier. In the scenario of FIG. 13A the wireless device 120 receives a collection of data samples and in the scenario of FIG. 13B the wireless device 120 receives successive data samples. Further, FIG. 13A shows the initialization if all samples are available when the number of clusters K and the initial cluster centroids are computed. FIG. 13B shows how the clusters are initiated when the samples are received one by one.

As illustrated in FIG. 13A, in Action 1301, the wireless device 120 gets a collection of data samples, and in Action 1302 the wireless device 120 performs K-means clustering for K=1, 2, . . . . In Action 1303, the wireless device 120 determined the best K, i.e. the wireless device 120 determines the number of clusters K giving the best MSE. The MSE decreases with increasing K so the number chosen for K is the best trade-off between the MSE and the number of cluster. Thus, in Action 1303 the wireless device 120 determines the number of clusters K such that increasing K would not result in a significant decrease in MSE. Confer FIG. 8, wherein the MSE decreases for K>3 but the rate of decrease is very low. In Action 1304, the wireless device 120 computes a number of initial cluster centroids for the K clusters, and in Action 1305, the data samples of the collection of data samples are associated to a respective cluster and the covariance for each cluster is calculated. In Action 1306, the wireless device 120 calculates anomaly thresholds.

As illustrated in FIG. 13B, in Action 1311, the wireless device 120 gets a training example. The training example may for example be a data sample. Sometimes in this disclosure the terms “training example” and data sample” are used interchangeably. In Action 1312, the wireless device 120 determines whether or not the number of cluster is lesser than a maximum number K of clusters. In other words, it is checked if more than K samples have been received. If not, i.e. the number clusters is lesser than K, then the new sample becomes a new cluster, cf. Action 1313. If we have K clusters already, i.e. the number of clusters is equal to K, two metrics are computed, cf. Action 1315 and 1316. One metric is computed when the new sample is added to one of the existing clusters and the other metric is computed when two clusters are merged and a new cluster is created from the new sample. The action that minimizes the new total MSE is chosen, cf. Actions 1317 and 1318.

If the number of clusters is lesser than the K, in Action 1314, the wireless device 120 finds the nearest cluster centroid for the training example. In Action 1315, the wireless device 120 computes the MSE that would result from adding the new sample to one of the existing clusters, and in Action 1316, the wireless device 120 computes the MSE that would result from merging all possible pairs of clusters and creating a new cluster comprising only the new sample. In Action 1317, the wireless device 120 determines whether or not the MSE that would result from adding the new sample to one of the existing clusters is lesser than the MSE that would result from merging all possible pairs of clusters and creating a new cluster comprising only the new sample. If the MSE that would result from adding the new sample to one of the existing clusters is lesser, the wireless device 120 in Action 1318 adds the data sample to the best cluster and in Action 1319 the wireless device 120 updates one or more out of cluster centroids, cluster counters, covariance and thresholds.

If the wireless device 120 in Action 1317 determines that the MSE that would result from adding the new sample to one of the existing clusters is higher than the MSE that would result from merging all possible pairs of clusters and creating a new cluster comprising only the new sample, the wireless device 120 in Action 1320 merges two clusters, e.g. the two best clusters, and the new data sample becomes a new cluster. By the expression “best clusters” is meant that the two clusters that result in the least MSE when merged.

FIG. 14 is a flowchart schematically illustrating an example of how some embodiments disclosed herein may be used during runtime of the wireless device 120.

In Action 1401, the wireless device 120 gets a training example, e.g. a data sample. The training example may be every sample of whatever it is, or some subset. This sampling may be triggered by some communication event, e.g., if a transmission went unexpectedly wrong, store the example.

In Action 1402, the wireless device 120 finds the nearest cluster and associates the sample with the cluster.

In Action 1403, the wireless device 120 performs anomaly detection between the sample and the selected cluster.

Alternatively to Action 1402 and 1403, the wireless device 120 may perform the anomaly detection for all the K clusters.

In Action 1404, the wireless device 120 determines whether or not the sample is anomalous for the selected cluster or all clusters.

If the sample is determined to be anomalous, the wireless device 120 in Action 1405 stores the anomalous sample as it is since it's an important training example in its own right.

If the sample is determined not to be anomalous, it belongs to one of the clusters. Thus, in Action 1406, the wireless device 120 adds the sample to best cluster and in Action 1407, the wireless device 120 updates the cluster counter by one for that cluster.

Optionally, in Action 1408, the wireless device 120 may update cluster centroid location and cluster axes. The means may be updated as follows: n=n+1, δ=x−m, and m′=m+δ/n. The covariance update is given above. If PCA is performed it may be recomputed based on the updated covariance matrices when a current covariance matrix is sufficiently different compared to when it was used to compute the PCA.

In Action 1409, the wireless device 120 determines whether or not it is time to transmit the compressed data to the network node 110. This may be the case when for example the communication load is sufficiently low, when the memory full, when the timer reached or similar.

If it is time to transmit, in Action 1410, the wireless device 120 transmits the compressed data to the network node 110. Further, the appropriate storage elements, timers, etc. may be reset.

If it is not time to transmit or after performing Action 1410, the wireless device 120 may repeat to perform the actions starting from Action 1401.

Optionally, the wireless device 120 may, during runtime, check if clusters may be merged without increasing the resulting variance too much. This operation has a K\hat{ }2 complexity and thus the number of clusters K should not be allowed to grow unnecessary large.

In some embodiments, covariance matrices are created and updated from the start. It should be understood that a data sample detected as an outlier in the anomaly detection is a potential new cluster head. For each new sample, the wireless device 120 may check if it's in a cluster or an outlier. In the latter case, the wireless device stores the sample as a new cluster head with one sample in the cluster, i.e. the cluster counter is set to one. True outliers will not get more data points and will thus be recorded as single points.

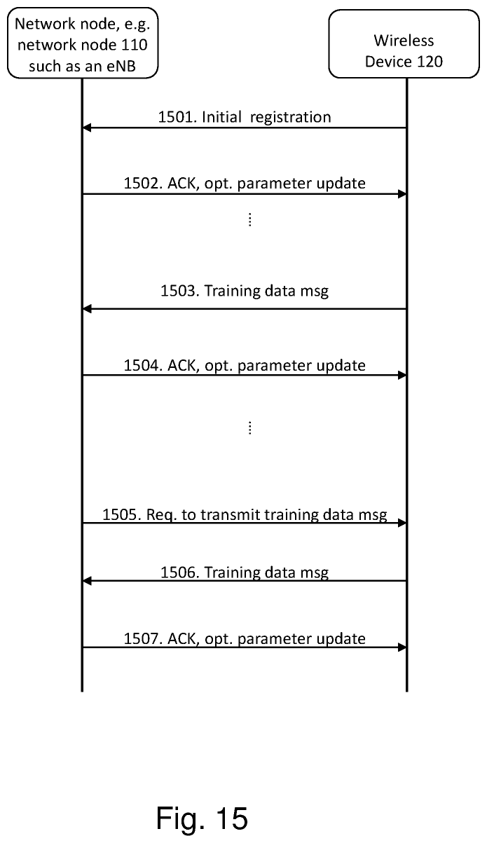

FIG. 15 is a combined flowchart and signalling scheme schematically illustrating embodiments of a method performed in a wireless communications system. FIG. 15 shows an example of message exchange between the wireless device 120 and the network node, e.g. the network node 110 such as the eNB. At an initial registration with the network node 110, cf. Action 1501, the wireless device 120 may request update of its parameter, or the network node 110 may offer parameter update, or mandate parameter update. Since the network node 110 may collect data from multiple wireless devices, e.g. from both the wireless device 120 and the wireless device 122, and also have access to regional and/or global data on relevant devices, the network node 110 may have more fine-tuned anomaly thresholds etc. If the wireless device is deployed in a unique environment, those common parameters may not be applicable to the wireless device, and it's preferable to keep the local parameters. Thus, whether parameter update takes place at initial registration depends on environment and system parameters. Therefore, in Action 1502, it is optional for the network node 110 to transmit the parameter updates.

When the data collection has progressed for some time, a number of samples, a number of outliers or other have been collected and the wireless device 120 in Action 1503 transmits its data, e.g. the compressed data, to the network node 110. After processing the data, the network node 110 may in Action 1504 send a parameter update.

The network node 110 may trigger a data transmission, e.g. if the network node 110 collects data from multiple wireless devices in similar settings to train its machine learning model. In such scenario, the network node 110 transmits in Action 1505 a request for data transmission, and in Action 1506 the wireless device 120 transmits its compressed data to the network node 110. In Action 1507, the network node 110 transmits an acknowledgement to the wireless device 120 acknowledging receipt of the compressed data. Further, the network node 110 may transmit parameter updates. If the network node gets input from other devices, it may use additional data to compute variances, cluster centroids etc. Then the network node may transmit parameters related to the compression, such as cluster centroids, variances, anomaly thresholds.

If the wireless device has machine learning capabilities then the parameter updates transmitted by the network node may also include parameters related to the machine learning mode, e.g., weights for a neural network, weights for regressors, decision boundaries for trees, or other relevant parameters for the machine learning model.

Further Extensions and Variations

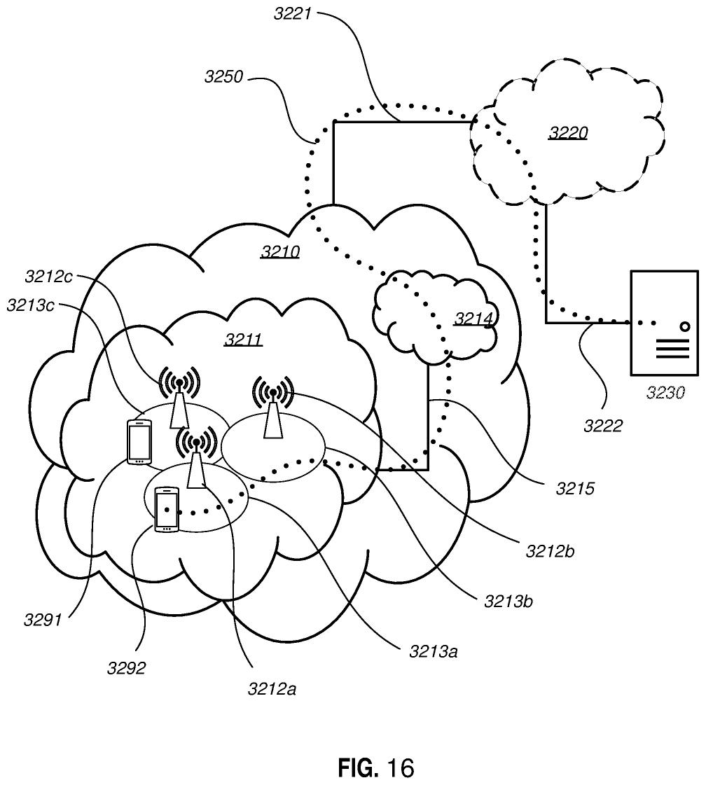

With reference to FIG. 16, in accordance with an embodiment, a communication system includes a telecommunication network 3210 such as the wireless communications network 100, e.g. a WLAN, such as a 3GPP-type cellular network, which comprises an access network 3211, such as a radio access network, e.g. the RAN 101, and a core network 3214, e.g. the CN 102. The access network 3211 comprises a plurality of base stations 3212a, 3212b, 3212c, such as the network node 110, 111, access nodes, AP STAs NBs, eNBs, gNBs or other types of wireless access points, each defining a corresponding coverage area 3213a, 3213b, 3213c. Each base station 3212a, 3212b, 3212c is connectable to the core network 3214 over a wired or wireless connection 3215. A first user equipment (UE) e.g. the wireless device 120, 122 such as a Non-AP STA 3291 located in coverage area 3213c is configured to wirelessly connect to, or be paged by, the corresponding base station 3212c. A second UE 3292 e.g. the wireless device 122 such as a Non-AP STA in coverage area 3213a is wirelessly connectable to the corresponding base station 3212a. While a plurality of UEs 3291, 3292 are illustrated in this example, the disclosed embodiments are equally applicable to a situation where a sole UE is in the coverage area or where a sole UE is connecting to the corresponding base station 3212.

The telecommunication network 3210 is itself connected to a host computer 3230, which may be embodied in the hardware and/or software of a standalone server, a cloud-implemented server, a distributed server or as processing resources in a server farm. The host computer 3230 may be under the ownership or control of a service provider, or may be operated by the service provider or on behalf of the service provider. The connections 3221, 3222 between the telecommunication network 3210 and the host computer 3230 may extend directly from the core network 3214 to the host computer 3230 or may go via an optional intermediate network 3220, e.g. the external network 200. The intermediate network 3220 may be one of, or a combination of more than one of, a public, private or hosted network; the intermediate network 3220, if any, may be a backbone network or the Internet; in particular, the intermediate network 3220 may comprise two or more sub-networks (not shown).

The communication system of FIG. 16 as a whole enables connectivity between one of the connected UEs 3291, 3292 and the host computer 3230. The connectivity may be described as an over-the-top (OTT) connection 3250. The host computer 3230 and the connected UEs 3291, 3292 are configured to communicate data and/or signaling via the OTT connection 3250, using the access network 3211, the core network 3214, any intermediate network 3220 and possible further infrastructure (not shown) as intermediaries. The OTT connection 3250 may be transparent in the sense that the participating communication devices through which the OTT connection 3250 passes are unaware of routing of uplink and downlink communications. For example, a base station 3212 may not or need not be informed about the past routing of an incoming downlink communication with data originating from a host computer 3230 to be forwarded (e.g., handed over) to a connected UE 3291. Similarly, the base station 3212 need not be aware of the future routing of an outgoing uplink communication originating from the UE 3291 towards the host computer 3230.

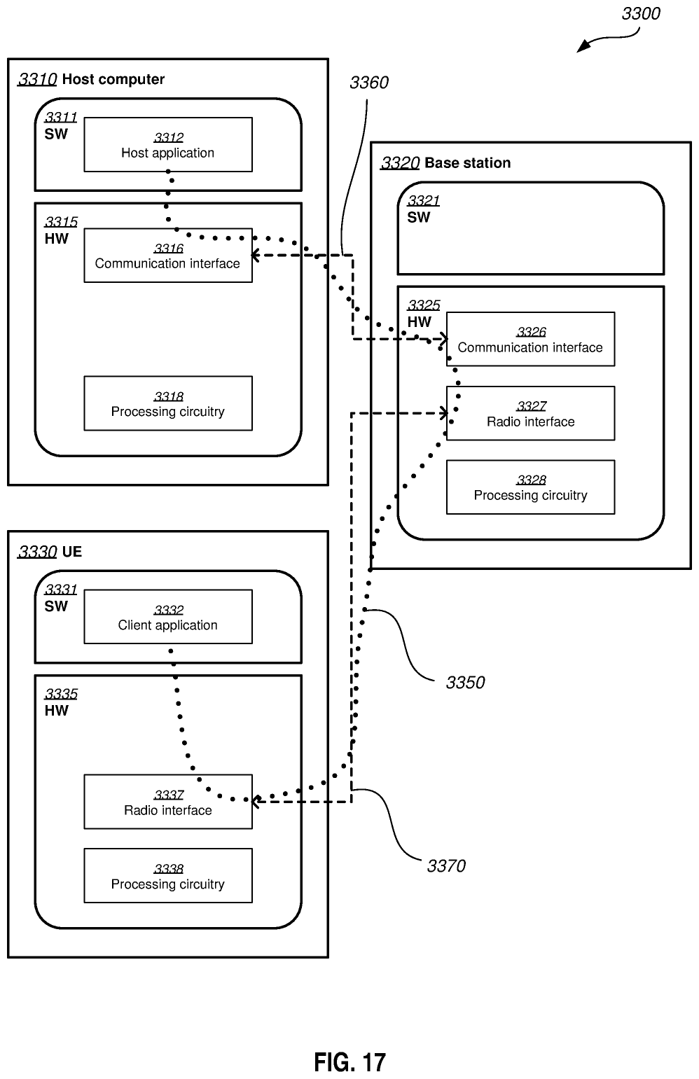

Example implementations, in accordance with an embodiment, of the UE, base station and host computer discussed in the preceding paragraphs will now be described with reference to FIG. 17. In a communication system 3300, a host computer 3310 comprises hardware 3315 including a communication interface 3316 configured to set up and maintain a wired or wireless connection with an interface of a different communication device of the communication system 3300. The host computer 3310 further comprises processing circuitry 3318, which may have storage and/or processing capabilities. In particular, the processing circuitry 3318 may comprise one or more programmable processors, application-specific integrated circuits, field programmable gate arrays or combinations of these (not shown) adapted to execute instructions. The host computer 3310 further comprises software 3311, which is stored in or accessible by the host computer 3310 and executable by the processing circuitry 3318. The software 3311 includes a host application 3312. The host application 3312 may be operable to provide a service to a remote user, such as a UE 3330 connecting via an OTT connection 3350 terminating at the UE 3330 and the host computer 3310. In providing the service to the remote user, the host application 3312 may provide user data which is transmitted using the OTT connection 3350.

The communication system 3300 further includes a base station 3320 provided in a telecommunication system and comprising hardware 3325 enabling it to communicate with the host computer 3310 and with the UE 3330. The hardware 3325 may include a communication interface 3326 for setting up and maintaining a wired or wireless connection with an interface of a different communication device of the communication system 3300, as well as a radio interface 3327 for setting up and maintaining at least a wireless connection 3370 with a UE 3330 located in a coverage area (not shown in FIG. 12) served by the base station 3320. The communication interface 3326 may be configured to facilitate a connection 3360 to the host computer 3310. The connection 3360 may be direct or it may pass through a core network (not shown in FIG. 12) of the telecommunication system and/or through one or more intermediate networks outside the telecommunication system. In the embodiment shown, the hardware 3325 of the base station 3320 further includes processing circuitry 3328, which may comprise one or more programmable processors, application-specific integrated circuits, field programmable gate arrays or combinations of these (not shown) adapted to execute instructions. The base station 3320 further has software 3321 stored internally or accessible via an external connection.

The communication system 3300 further includes the UE 3330 already referred to. Its hardware 3335 may include a radio interface 3337 configured to set up and maintain a wireless connection 3370 with a base station serving a coverage area in which the UE 3330 is currently located. The hardware 3335 of the UE 3330 further includes processing circuitry 3338, which may comprise one or more programmable processors, application-specific integrated circuits, field programmable gate arrays or combinations of these (not shown) adapted to execute instructions. The UE 3330 further comprises software 3331, which is stored in or accessible by the UE 3330 and executable by the processing circuitry 3338. The software 3331 includes a client application 3332. The client application 3332 may be operable to provide a service to a human or non-human user via the UE 3330, with the support of the host computer 3310. In the host computer 3310, an executing host application 3312 may communicate with the executing client application 3332 via the OTT connection 3350 terminating at the UE 3330 and the host computer 3310. In providing the service to the user, the client application 3332 may receive request data from the host application 3312 and provide user data in response to the request data. The OTT connection 3350 may transfer both the request data and the user data. The client application 3332 may interact with the user to generate the user data that it provides. It is noted that the host computer 3310, base station 3320 and UE 3330 illustrated in FIG. 12 may be identical to the host computer 3230, one of the base stations 3212a, 3212b, 3212c and one of the UEs 3291, 3292 of FIG. 16, respectively. This is to say, the inner workings of these entities may be as shown in FIG. 17 and independently, the surrounding network topology may be that of FIG. 16.

In FIG. 17, the OTT connection 3350 has been drawn abstractly to illustrate the communication between the host computer 3310 and the use equipment 3330 via the base station 3320, without explicit reference to any intermediary devices and the precise routing of messages via these devices. Network infrastructure may determine the routing, which it may be configured to hide from the UE 3330 or from the service provider operating the host computer 3310, or both. While the OTT connection 3350 is active, the network infrastructure may further take decisions by which it dynamically changes the routing (e.g., on the basis of load balancing consideration or reconfiguration of the network).

The wireless connection 3370 between the UE 3330 and the base station 3320 is in accordance with the teachings of the embodiments described throughout this disclosure. One or more of the various embodiments improve the performance of OTT services provided to the UE 3330 using the OTT connection 3350, in which the wireless connection 3370 forms the last segment. More precisely, the teachings of these embodiments may reduce the signalling overhead and thus improve the data rate. Thereby, providing benefits such as reduced user waiting time, relaxed restriction on file size, and/or better responsiveness.

A measurement procedure may be provided for the purpose of monitoring data rate, latency and other factors on which the one or more embodiments improve. There may further be an optional network functionality for reconfiguring the OTT connection 3350 between the host computer 3310 and UE 3330, in response to variations in the measurement results. The measurement procedure and/or the network functionality for reconfiguring the OTT connection 3350 may be implemented in the software 3311 of the host computer 3310 or in the software 3331 of the UE 3330, or both. In embodiments, sensors (not shown) may be deployed in or in association with communication devices through which the OTT connection 3350 passes; the sensors may participate in the measurement procedure by supplying values of the monitored quantities exemplified above, or supplying values of other physical quantities from which software 3311, 3331 may compute or estimate the monitored quantities. The reconfiguring of the OTT connection 3350 may include message format, retransmission settings, preferred routing etc.; the reconfiguring need not affect the base station 3320, and it may be unknown or imperceptible to the base station 3320. Such procedures and functionalities may be known and practiced in the art. In certain embodiments, measurements may involve proprietary UE signalling facilitating the host computer's 3310 measurements of throughput, propagation times, latency and the like. The measurements may be implemented in that the software 3311, 3331 causes messages to be transmitted, in particular empty or ‘dummy’ messages, using the OTT connection 3350 while it monitors propagation times, errors etc.

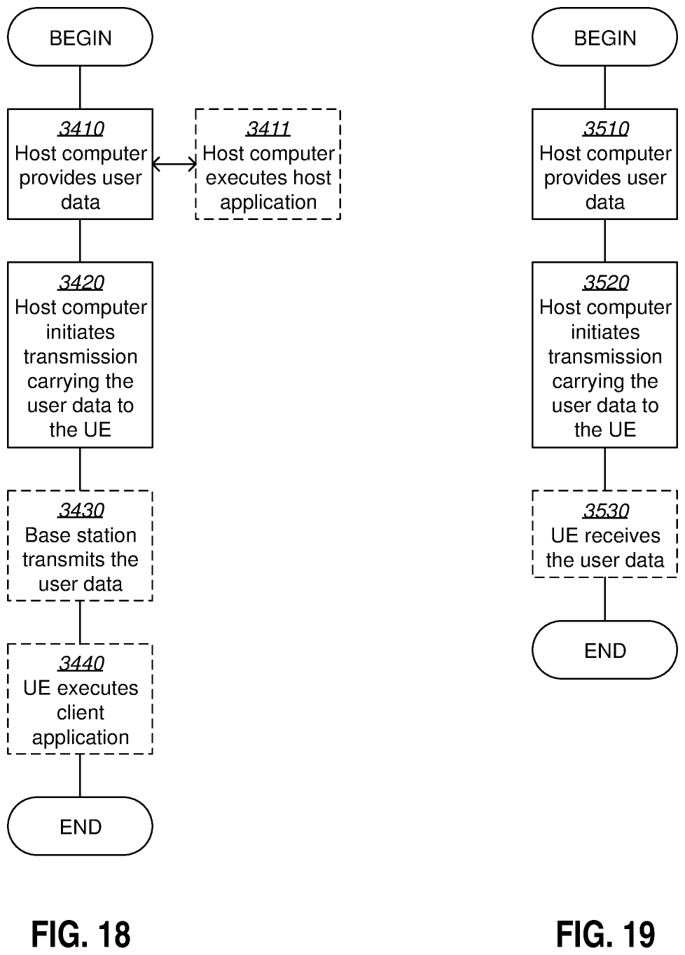

FIG. 18 is a flowchart illustrating a method implemented in a communication system, in accordance with one embodiment. The communication system includes a host computer, a base station such as an AP STA, and a UE such as a Non-AP STA which may be those described with reference to FIGS. 16 and 17. For simplicity of the present disclosure, only drawing references to FIG. 18 will be included in this section. In a first action 3410 of the method, the host computer provides user data. In an optional subaction 3411 of the first action 3410, the host computer provides the user data by executing a host application. In a second action 3420, the host computer initiates a transmission carrying the user data to the UE. In an optional third action 3430, the base station transmits to the UE the user data which was carried in the transmission that the host computer initiated, in accordance with the teachings of the embodiments described throughout this disclosure. In an optional fourth action 3440, the UE executes a client application associated with the host application executed by the host computer.

FIG. 19 is a flowchart illustrating a method implemented in a communication system, in accordance with one embodiment. The communication system includes a host computer, a base station such as an AP STA, and a UE such as a Non-AP STA which may be those described with reference to FIGS. 16 and 17. For simplicity of the present disclosure, only drawing references to FIG. 18 will be included in this section. In a first action 3510 of the method, the host computer provides user data. In an optional subaction (not shown) the host computer provides the user data by executing a host application. In a second action 3520, the host computer initiates a transmission carrying the user data to the UE. The transmission may pass via the base station, in accordance with the teachings of the embodiments described throughout this disclosure. In an optional third action 3530, the UE receives the user data carried in the transmission.

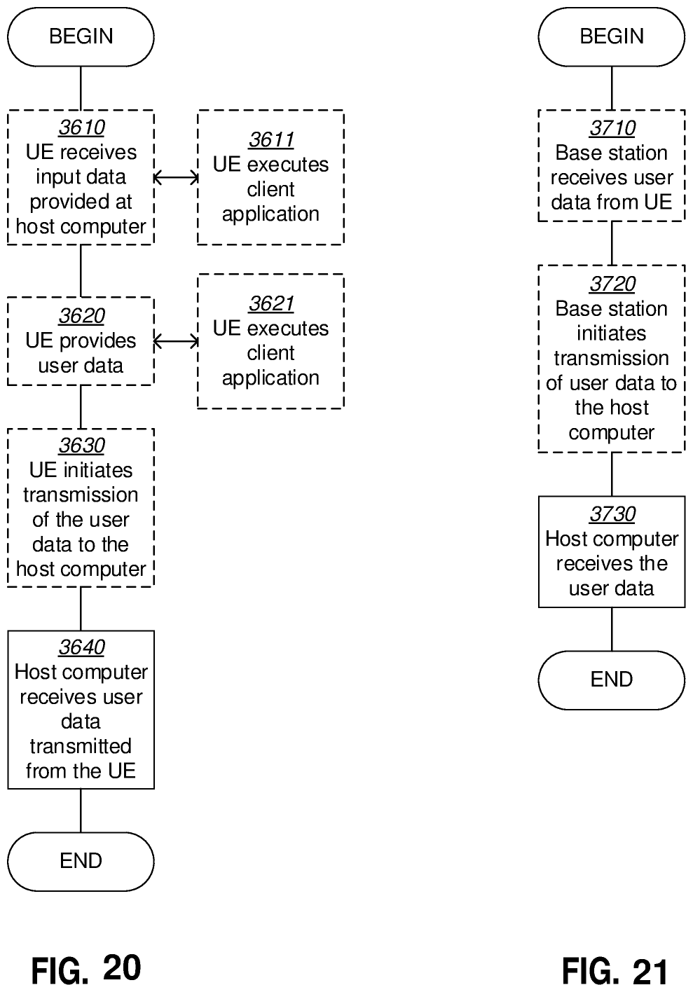

FIG. 20 is a flowchart illustrating a method implemented in a communication system, in accordance with one embodiment. The communication system includes a host computer, a base station such as a AP STA, and a UE such as a Non-AP STA which may be those described with reference to FIGS. 16 and 17. For simplicity of the present disclosure, only drawing references to FIG. 15 will be included in this section. In an optional first action 3610 of the method, the UE receives input data provided by the host computer. Additionally or alternatively, in an optional second action 3620, the UE provides user data. In an optional subaction 3621 of the second action 3620, the UE provides the user data by executing a client application. In a further optional subaction 3611 of the first action 3610, the UE executes a client application which provides the user data in reaction to the received input data provided by the host computer. In providing the user data, the executed client application may further consider user input received from the user. Regardless of the specific manner in which the user data was provided, the UE initiates, in an optional third subaction 3630, transmission of the user data to the host computer. In a fourth action 3640 of the method, the host computer receives the user data transmitted from the UE, in accordance with the teachings of the embodiments described throughout this disclosure.

FIG. 21 is a flowchart illustrating a method implemented in a communication system, in accordance with one embodiment. The communication system includes a host computer, a base station such as a AP STA, and a UE such as a Non-AP STA which may be those described with reference to FIGS. 17 and 18. For simplicity of the present disclosure, only drawing references to FIG. 21 will be included in this section. In an optional first action 3710 of the method, in accordance with the teachings of the embodiments described throughout this disclosure, the base station receives user data from the UE. In an optional second action 3720, the base station initiates transmission of the received user data to the host computer. In a third action 3730, the host computer receives the user data carried in the transmission initiated by the base station.

When using the word “comprise” or “comprising” it shall be interpreted as non-limiting, i.e. meaning “consist at least of”.

The embodiments herein are not limited to the above described preferred embodiments. Various alternatives, modifications and equivalents may be used.

### Abbreviation Explanation

AI Artificial Intelligence

AIC Akaike Information Criterion

BIC Bayesian Information Criterion

BS Base Station

CSI Channel State Information

DIC Deviance Information Criterion

EM Expectation Maximization

eNB Evolved Node BUE User Equipment

AI Artificial Intelligence

AIC Akaike Information Criterion

BIC Bayesian Information Criterion

BS Base Station

CSI Channel State Information

DIC Deviance Information Criterion

EM Expectation Maximization

eNB Evolved Node B

FN False Negative

FP False Positive

GMM Gaussian Mixture Model

HW Hardware

KL Kullback-Leibler

MCS Modulation and Coding Subsystem

MI Machine Intelligence

ML Machine Learning

MLA Machine Learning Architecture

MSE Mean Squared Error

PCA Principal Component Analysis

RF Radio Frequency

TN True Negative

TP True Positive

UE User Equipment

1. A method performed in a wireless device for assisting a network node to perform training of a machine learning model, the wireless device and the network node operate in a wireless communications system, the method comprising:
collecting a number of successive data samples for training of the machine learning model comprised in the network node;
successively creating compressed data by:
associating each collected data sample to a cluster, which cluster has a cluster centroid, a cluster counter representative of a number of collected data samples determined to be normal and being associated with the cluster, and a number of outlier collected data samples associated with the cluster, the number of outlier collected data samples being a number of collected data samples determined to be anomalous with respect to the cluster,
updating the cluster centroid to correspond to a mean position of all normal data samples that are associated with the cluster, and
increasing the cluster counter by one for each normal data sample that is associated with the cluster; and
transmitting, to the network node, the compressed data comprising the cluster centroid, the cluster counter, and the number of outlier collected data samples, which compressed data is to be used in the training of the machine learning model.

2. The method of claim 1, further comprising:
storing, in a memory, the cluster centroid, the cluster counter and the number of outlier collected data samples associated with the cluster as the compressed data.

3. The method of claim 1, wherein the successively creating of the compressed data comprises:
associating only a single normal data sample out of the number of collected data samples to each cluster such that the normal data sample is the cluster centroid, the number of normal data samples associated with the cluster is one, and the number of outlier collected data samples associated with the cluster is zero; and when a number of clusters has reached a maximum number, and the method further comprises:
merging one or more of the clusters into a merged cluster by updating the cluster centroid to correspond to a mean position of all associated normal data samples of the one or more clusters, and by determining the cluster counter for the merged cluster to be equal to the number of all normal data samples associated with the one or more clusters.

4. The method of claim 3, wherein the merging of the one or more clusters into the merged cluster comprises:
merging the one or more clusters into the merged cluster when a determined variance value of the merged cluster is lower than the respective variance value of the one or more clusters.

5. The method of claim 1, wherein the successively creating of the compressed data further comprises:
performing anomaly detection between the collected data sample and the associated cluster to determine whether the collected data sample is one of an anomalous data sample and a normal data sample.

6. The method of claim 5, wherein the performing of the anomaly detection between the collected data sample and the determined associated cluster comprises:
determining a distance between the cluster centroid of the associated cluster and the collected data sample;
determining the collected data sample to be an anomalous data sample when the distance is equal to or above a threshold value; and
determining the collected data sample to be a normal data sample when the distance is below the threshold value.

7. The method of claim 1, comprising:
determining a maximum number of clusters to be used based on a storage capacity of the memory storing the compressed data.

8. The method of claim 1, comprising:
determining a maximum number of clusters to be used by increasing a number of clusters until a respective variance value of data samples associated with the respective cluster is below a variance threshold value.

9. The method of claim 1, further comprising:
determining one or more directions of a multidimensional distribution of the normal data samples associated with the cluster,
optionally disregarding one or more directions of the multidimensional distribution along which the normal data samples have a variance value for the one or more directions that is below a variance threshold value; and
transmitting, to the network node, the variance value for the one or more directions of the normal data samples having a variance value above the variance threshold value.

10. The method of claim 1, wherein the transmitting of the compressed data to the network node comprises:
transmitting the compressed data to the network node when a load on a communications link between the wireless device and the network node is below a load threshold value; and
wherein the method further comprises:
removing the transmitted compressed data from the memory.

11. The method of claim 1, further comprising:
receiving, from the network node, a request for compressed data to be used in the training of the machine learning model, and wherein the transmitting of the compressed data to the network node comprises:
transmitting the compressed data to the network node in response to the received request.

12. A method performed in a network node for training of a machine learning model, the network node and a wireless device operate in a wireless communications system, the method comprising:
receiving, from the wireless device, compressed data corresponding to a cluster centroid, a cluster counter, and a number of outlier collected data samples associated with a cluster, which compressed data is a compressed representation of data samples collected by the wireless device; and
training the machine learning model using the received compressed data as input to the machine learning model.

13. The method of claim 12, further comprising:
receiving, from the wireless device, a variance value per direction of a multidimensional distribution of the collected data samples associated with the cluster;
generating a number of random data samples based on the received cluster centroid and the received variance values, wherein the number of random data samples is proportional to the cluster counter; and
wherein the training of the machine learning model using the received compressed data as input to the machine learning model further comprises:
training the machine learning model using the one or more generated random data samples as input to the machine learning model.

14. The method of claim 12, further comprising:
updating the machine learning model based on a result of the training.

15. A wireless device for assisting a network node to perform training of a machine learning model, the wireless device and the network node being configured to operate in a wireless communications system and the wireless device is configured to:
collect a number of successive data samples for training of the machine learning model comprised in the network node;
successively create compressed data by being configured to:
associate each collected data sample to a cluster, which cluster has a cluster centroid, a cluster counter representative of a number of collected data samples determined to be normal and being associated with the cluster, and a number of outlier collected data samples associated with the cluster, the number of outlier collected data samples being a number of collected data samples determined to be anomalous with respect to the cluster,
update the cluster centroid to correspond to a mean position of all normal data samples that are associated with the cluster, and
increase the cluster counter by one for each normal data sample that is associated with the cluster; and
transmit, to the network node, the compressed data comprising the cluster centroid, the cluster counter and the number of outlier collected data samples, which compressed data is to be used in the training of the machine learning model.

16. The wireless device of claim 15, further configured to:
store, in a memory, the cluster centroid, the cluster counter and the number of outlier collected data samples associated with the cluster as the compressed data.

17. The wireless device of claim 15, wherein the wireless device is configured to successively create the compressed data by being further configured to:
associate only a single normal data sample out of the number of collected data samples to each cluster such that the normal data sample is the cluster centroid, the number of normal data samples associated with the cluster is one, and the number of outlier collected data samples associated with the cluster is zero; and
when a number of clusters has reached a maximum number, merge one or more of the clusters into a merged cluster by updating the cluster centroid to correspond to a mean position of all associated normal data samples of the one or more clusters, and by determining the cluster counter for the merged cluster to be equal to the number of all normal data samples associated with the one or more clusters.

18.-25. (canceled)

26. A network node for training of a machine learning model, the network node and a wireless device being configured to operate in a wireless communications system and the network node is configured to:
receive, from the wireless device, compressed data corresponding to a cluster centroid, a cluster counter, and a number of outlier collected data samples associated with a cluster, which compressed data is a compressed representation of data samples collected by the wireless device; and
train the machine learning model using the received compressed data as input to the machine learning model.

27. The network node of claim 26, further configured to:
receive, from the wireless device, a variance value per direction of a multidimensional distribution of the collected data samples associated with the cluster;
generate a number of random data samples based on the received cluster centroid and the received variance values, wherein the number of random data samples is proportional to the cluster counter; and wherein the network node is configured to train of the machine learning model using the received compressed data as input to the machine learning model by further being configured to:
train the machine learning model using the one or more generated random data samples as input to the machine learning model.

28. The network node of claim 26, further configured to:
update the machine learning model based on a result of the training.

29. (canceled)

30. (canceled)
